(19) United States
(12) Patent Application Publication
(10) Pub. No.: US 2025/0089495 A1
(43) Pub. Date: Mar. 13, 2025

(54) DISPLAY DEVICE

(71) Applicant: Samsung Display Co., LTD., Yongin-si (KR)

(72) Inventor: Jong Hyun CHOI, Yongin-si (KR)

(21) Appl. No.: 18/662,801

(22) Filed: May 13, 2024

(30) Foreign Application Priority Data
Sep. 12, 2023 (KR) 10-2023-0121084

(51) Int. Cl. H10K 59/131; H10K 59/121; H10K 59/123; H10K 59/40; H10K 59/65

(52) U.S. Cl. CPC H10K 59/131; H10K 59/1216; H10K 59/123; H10K 59/40; H10K 59/65

(57) ABSTRACT

A display device is provided including a substrate; a circuit layer; and an element layer. The circuit layer includes a first light emitting pixel driver and a second light emitting pixel driver neighboring each other in a second direction; a third light emitting pixel driver and a fourth light emitting pixel driver respectively neighboring the first light emitting pixel driver and the second light emitting pixel driver in a first direction; and one first-direction line extending in the first direction and adjacent to a boundary between the first light emitting pixel driver and the second light emitting pixel driver and a boundary between the third light emitting pixel driver and the fourth light emitting pixel driver. The one first-direction line includes: a first main extension portion extending in the first direction; and a bypass portion connected to the first main extension portion and bypassing a light transmitting area.

### CROSS-REFERENCED TO RELATED APPLICATION

The present application claims priority to and the benefit of Korean Patent Application No. 10-2023-0121084, filed on Sep. 12, 2023, in the Korean Intellectual Property Office, the entire disclosure of which is incorporated herein by reference.

### BACKGROUND

### 1. Field

Aspects of one or more embodiments of the present disclosure relate to a display device.

### 2. Description of the Related Art

As the information society develops, demand for display devices for displaying images are increasing in various forms. For example, display devices are applied to various electronic devices, such as smartphones, digital cameras, notebook computers, navigation devices, and smart televisions.

The display devices may be flat panel display devices, such as liquid crystal display devices, field emission display devices, and light emitting display devices. Here, the light emitting display devices may include organic light emitting display devices including organic light emitting elements, inorganic light emitting display devices including inorganic light emitting elements, such as inorganic semiconductors, and ultra-small light emitting display devices including ultra-small light emitting elements.

An organic light emitting display device displays an image using light emitting elements, each including a light emitting layer of an organic light emitting material. Because organic light emitting display devices implement image display using self-luminous elements, they can have relatively superior performance in terms of power consumption, response speed, luminous efficiency, luminance, and wide viewing angle compared with other display devices.

A surface of a display device may be a display surface including a display area where an image is displayed and a non-display area disposed around the display area. Emission areas that emit light with respective luminances and colors may be arranged in the display area.

The above information disclosed in this Background section is for enhancement of understanding of the background of the present disclosure, and therefore, it may contain information that does not constitute prior art.

### SUMMARY

An electronic device equipped with the display device may include optical sensors, such as a camera, an illuminance sensor, and a distance sensor.

If the optical sensors are disposed below the display surface of the display device, they may overlap the non-display area of the display device to secure their optical path. In this case, however, the width of the non-display area increases due to the arrangement of the optical sensors.

To solve this problem, a portion of the display area of the display device may include both an emission area and a light transmitting area, and the optical sensors may overlap the portion of the display area. In this case, due to the presence of the light transmitting area, the portion of the display area which overlaps the optical sensors may have lower resolution than the other portion, resulting in deterioration of display quality.

Aspects of some embodiments of the present disclosure are directed to a display device wherein deterioration of the display quality can be reduced or prevented if a portion of a display area overlaps optical sensors.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to some aspects of the present disclosure, there is provided a display device including: a substrate including a display area including emission areas; a circuit layer on the substrate; and an element layer on the circuit layer, and including light emitting elements in the emission areas, respectively. The circuit layer includes: light emitting pixel drivers electrically connected to the light emitting elements, respectively, and located side by side with each other in a first direction and a second direction crossing the first direction. The light emitting pixel drivers include: a first light emitting pixel driver and a second light emitting pixel driver adjacent to each other in the second direction; and a third light emitting pixel driver and a fourth light emitting pixel driver adjacent to the first light emitting pixel driver and the second light emitting pixel driver, respectively, in the first direction. The circuit layer further includes one first-direction line extending in the first direction, and adjacent to a boundary between the first light emitting pixel driver and the second light emitting pixel driver, and to a boundary between the third light emitting pixel driver and the fourth light emitting pixel driver. The one first-direction line includes: a first main extension portion extending in the first direction; and a bypass portion connected to the first main extension portion, and bypassing a light transmitting area of the display area including a contact point at which the first light emitting pixel driver, the second light emitting pixel driver, the third light emitting pixel driver, and the fourth light emitting pixel driver contact each other.

The first light emitting pixel driver, the second light emitting pixel driver, the third light emitting pixel driver, and the fourth light emitting pixel driver May be electrically connected to the one first-direction line; and the one first-direction line may be one of a plurality of bias voltage lines configured to transmit bias voltages to the light emitting pixel drivers.

The circuit layer may further include an anode initialization voltage line configured to transmit an anode initialization voltage to the light emitting pixel drivers. The anode initialization voltage line may include: a second main extension portion adjacent to the first main extension portion, and extending in the first direction; and a first sub-protruding portion protruding from the second main extension portion to extend in the second direction, and crossing the one first-direction line. The second main extension portion may overlap with the first light emitting pixel driver; and an end of the first sub-protruding portion may overlap with the second light emitting pixel driver.

The circuit layer may further include: a first anode initialization voltage line adjacent to a side of the one of the plurality of bias voltage lines in the second direction, extending in the first direction, and configured to transmit a first anode initialization voltage; and a second anode initialization voltage line adjacent to another side of the one of the plurality of bias voltage lines in the second direction, extending in the first direction, and configured to transmit a second anode initialization voltage having a different voltage level from that of the first anode initialization voltage. The first anode initialization voltage line may overlap with the first light emitting pixel driver, and may be electrically connected to the first light emitting pixel driver and the second light emitting pixel driver; and the second anode initialization voltage line may overlap with the fourth light emitting pixel driver, and may be electrically connected to the third light emitting pixel driver and the fourth light emitting pixel driver.

The circuit layer may further include a bias control line configured to transmit a bias control signal to the light emitting pixel drivers. The bias control line may include: a third main extension portion adjacent to a side of the one of the plurality of bias voltage lines in the second direction, and extending in the first direction; and a second sub-protruding portion protruding from the third main extension portion to extend in the second direction, and crossing the one first-direction line. The third main extension portion may overlap with the first light emitting pixel driver; and an end of the second sub-protruding portion may overlap with the second light emitting pixel driver.

The circuit layer may further include: an emission control line adjacent to the bias control line, extending in the first direction, and overlapping with the first light emitting pixel driver and the third light emitting pixel driver, the emission control line being configured to transmit an emission control signal to the light emitting pixel drivers; an emission control auxiliary line extending in the first direction, spaced from the emission control line in the second direction, and overlapping with the second light emitting pixel driver and the fourth light emitting pixel driver; and an emission control connection line extending in the second direction, electrically connected to the emission control line and the emission control auxiliary line, and crossing the one first-direction line.

The circuit layer may further include a gate initialization voltage line configured to transmit a gate initialization voltage to the light emitting pixel drivers. The light emitting pixel drivers may further include a fifth light emitting pixel driver adjacent to the first light emitting pixel driver in the second direction. The first light emitting pixel driver may be located between the second light emitting pixel driver and the fifth light emitting pixel driver in the second direction; and the first light emitting pixel driver and the fifth light emitting pixel driver may be electrically connected to one gate initialization voltage line located adjacent to a boundary between the first light emitting pixel driver and the fifth light emitting pixel driver.

The circuit layer may further include a scan initialization line configured to transmit a scan initialization signal to the light emitting pixel drivers. The scan initialization line may include: a fourth main extension portion adjacent to the gate initialization voltage line, and extending in the first direction; and a third sub-protruding portion protruding from the fourth main extension portion, and extending in the second direction. The fourth main extension portion may overlap with the fifth light emitting pixel driver, and an end of the third sub-protruding portion may overlap with the first light emitting pixel driver.

The circuit layer may further include: a gate control line extending in the first direction, overlapping with the fifth light emitting pixel driver, and configured to transmit a gate control signal to the light emitting pixel drivers; a gate control auxiliary line spaced from the gate control line in the second direction, extending in the first direction, and overlapping with the first light emitting pixel driver; and a gate control connection line extending in the second direction, electrically connected to the gate control line and the gate control auxiliary line, and crossing the gate initialization voltage line.

The circuit layer may further include: a first semiconductor layer on the substrate; a first gate insulating layer covering the first semiconductor layer; a first gate conductive layer on the first gate insulating layer; a second gate insulating layer covering the first gate conductive layer; a second gate conductive layer on the second gate insulating layer; a first interlayer insulating layer covering the second gate conductive layer; a second semiconductor layer on the first interlayer insulating layer; a third gate insulating layer covering the second semiconductor layer; a third gate conductive layer on the third gate insulating layer; a second interlayer insulating layer covering the third gate conductive layer; a first source-drain conductive layer on the second interlayer insulating layer; a first planarization layer covering the first source-drain conductive layer; a second source-drain conductive layer on the first planarization layer; and a second planarization layer covering the second source-drain conductive layer. Each of the light emitting pixel drivers may include: a first transistor electrically connected between a first node and a second node; a pixel capacitor electrically connected between a first power line and a third node, the first power line being configured to transmit a first power; a second transistor electrically connected between a data line and the first node, the data line being configured to transmit a data signal; a third transistor electrically connected between the second node and the third node; a fourth transistor electrically connected between a gate initialization voltage line and the third node, the gate initialization voltage line being configured to transmit a gate initialization voltage; a fifth transistor electrically connected between the first power line and the first node; a sixth transistor electrically connected between the second node and a fourth node; a seventh transistor electrically connected between an anode initialization voltage line and the fourth node, the anode initialization voltage line being configured to transmit an anode initialization voltage; and an eighth transistor electrically connected between the one of the plurality of bias voltage lines and the first node. The first node may be electrically connected to a first electrode of the first transistor; the second node may be electrically connected to a second electrode of the first transistor; the third node may be electrically connected to a gate electrode of the first transistor; and the fourth node may be electrically connected to one of the light emitting elements. Each of the first transistor, the second transistor, the fifth transistor, the sixth transistor, the seventh transistor, and the eight transistor may include: a gate electrode; a channel portion overlapping with the gate electrode; a first electrode portion connected to a side of the channel portion; and a second electrode portion connected to another side of the channel portion. Each of the third transistor and the fourth transistor may include: a first gate electrode and a second gate electrode at least partially overlapping with each other; a channel portion between the first gate electrode and the second gate electrode; a first electrode portion connected to a side of the channel portion; and a second electrode portion connected to another side of the channel portion. The channel portion, the first electrode portion, and the second electrode portion of each of the first transistor, the second transistor, the fifth transistor, the sixth transistor, the seventh transistor, and the eighth transistor may be parts of the first semiconductor layer; and the channel portion, the first electrode portion, and the second electrode portion of each of the third transistor and the fourth transistor may be parts of the second semiconductor layer.

The first semiconductor layer and the second semiconductor layer of the first light emitting pixel driver may be symmetrical to the first semiconductor layer and the second semiconductor layer of the third light emitting pixel driver with respect to a boundary between the first light emitting pixel driver and the third light emitting pixel driver.

The first semiconductor layer of the first light emitting pixel driver may be symmetrical to the first semiconductor layer of the second light emitting pixel driver with respect to the boundary between the first light emitting pixel driver and the second light emitting pixel driver.

The channel portion of the first transistor of the first light emitting pixel driver may be congruent with the channel portion of the first transistor of the second light emitting pixel driver.

According to some aspects of the present disclosure, there is provided a display device including a substrate including a display area including emission areas; a circuit layer on the substrate; and an element layer on the circuit layer, and including light emitting elements in the emission areas, respectively, wherein the circuit layer includes: light emitting pixel drivers electrically connected to the light emitting elements, respectively, and located side by side with each other in a first direction and a second direction crossing the first direction; a first semiconductor layer on the substrate; a first gate insulating layer covering the first semiconductor layer; a first gate conductive layer on the first gate insulating layer; a second gate insulating layer covering the first gate conductive layer; a second gate conductive layer on the second gate insulating layer; a first interlayer insulating layer covering the second gate conductive layer; a second semiconductor layer on the first interlayer insulating layer; a third gate insulating layer covering the second semiconductor layer; a third gate conductive layer on the third gate insulating layer; and a second interlayer insulating layer covering the third gate conductive layer. Each of the light emitting pixel drivers includes: a first transistor electrically connected between a first node and a second node; a pixel capacitor electrically connected between a first power line and a third node, the first power line being configured to transmit a first power; a second transistor electrically connected between a data line and the first node, the data line being configured to transmit a data signal; a third transistor electrically connected between the second node and the third node; and a fourth transistor electrically connected between a gate initialization voltage line and the third node, the gate initialization voltage line being configured to transmit a gate initialization voltage. The first node is electrically connected to a first electrode of the first transistor; the second node is electrically connected to a second electrode of the first transistor; and the third node is electrically connected to a gate electrode of the first transistor. Each of the first transistor and the second transistor includes: a gate electrode; a channel portion overlapping with the gate electrode; a first electrode portion connected to a side of the channel portion; and a second electrode portion connected to another side of the channel portion. Each of the third transistor and the fourth transistor includes: a first gate electrode and a second gate electrode at least partially overlapping with each other; a channel portion between the first gate electrode and the second gate electrode; a first electrode portion connected to a side of the channel portion; and a second electrode portion connected to another side of the channel portion. The channel portion, the first electrode portion, and the second electrode portion of each of the first transistor and the second transistor are parts of the first semiconductor layer; and the channel portion, the first electrode portion, and the second electrode portion of each of the third transistor and the fourth transistor are parts of the second semiconductor layer. The light emitting pixel drivers include a first light emitting pixel driver and a second light emitting pixel driver adjacent to each other in the second direction. The channel portion of the first transistor of the first light emitting pixel driver is congruent with the channel portion of the first transistor of the second light emitting pixel driver.

The light emitting pixel drivers may further include a third light emitting pixel driver and a fourth light emitting pixel driver adjacent to the first light emitting pixel driver and the second light emitting pixel driver, respectively, in the first direction; the circuit layer may further include one first-direction line extending in the first direction, and adjacent to a boundary between the first light emitting pixel driver and the second light emitting pixel driver, and to a boundary between the third light emitting pixel driver and the fourth light emitting pixel driver; the first light emitting pixel driver, the second light emitting pixel driver, the third light emitting pixel driver, and the fourth light emitting pixel driver may be electrically connected to the one first-direction line; and the one first-direction line may include: a first main extension portion extending in the first direction; and a bypass portion connected to the first main extension portion and bypassing a light transmitting area of the display area including a contact point at which the first light emitting pixel driver, the second light emitting pixel driver, the third light emitting pixel driver, and the fourth light emitting pixel driver contact each other.

Each of the light emitting pixel drivers may further include: a fifth transistor electrically connected between the first power line and the first node; a sixth transistor electrically connected between the second node and a fourth node; a seventh transistor electrically connected between an anode initialization voltage line and the fourth node, the anode initialization voltage line being configured to transmit an anode initialization voltage; and an eighth transistor electrically connected between a bias voltage line and the first node, the bias voltage line being configured to transmit a bias voltage. The fourth node may be electrically connected to one of the light emitting elements, and the one first-direction line may be the bias voltage line.

The anode initialization voltage line may include: a second main extension portion adjacent to the first main extension portion of the bias voltage line, and extending in the first direction; and a first sub-protruding portion protruding from the second main extension portion to extend in the second direction, and crossing the one first-direction line. The second main extension portion may overlap with the first light emitting pixel driver; and an end of the first sub-protruding portion may overlap with the second light emitting pixel driver.

The circuit layer may further include: a first anode initialization voltage line adjacent to a side of the bias voltage line in the second direction, extending in the first direction, and configured to transmit a first anode initialization voltage; and a second anode initialization voltage line adjacent to another side of the bias voltage line in the second direction, extending in the first direction, and configured to transmit a second anode initialization voltage having a different voltage level from that of the first anode initialization voltage. The first anode initialization voltage line may overlap with the first light emitting pixel driver, and may be electrically connected to the first light emitting pixel driver and the second light emitting pixel driver; and the second anode initialization voltage line may overlap with the fourth light emitting pixel driver, and may be electrically connected to the third light emitting pixel driver and the fourth light emitting pixel driver.

The circuit layer may further include a bias control line configured to transmit a bias control signal to the light emitting pixel drivers; the seventh transistor and the eighth transistor may be configured to be turned on by the bias control signal; the bias control line may include: a third main extension portion adjacent to a side of the bias voltage line in the second direction, and extending in the first direction; and a second sub-protruding portion protruding from the third main extension portion to extend in the second direction, and crossing the one first-direction line; the third main extension portion may overlap with the first light emitting pixel driver; and an end of the second sub-protruding portion may overlap with the second light emitting pixel driver.

The light emitting pixel drivers may further include a fifth light emitting pixel driver adjacent to the first light emitting pixel driver in the second direction. The first light emitting pixel driver may be located between the second light emitting pixel driver and the fifth light emitting pixel driver in the second direction, and the first light emitting pixel driver and the fifth light emitting pixel driver may be electrically connected to one gate initialization voltage line adjacent to a boundary between the first light emitting pixel driver and the fifth light emitting pixel driver.

According to some embodiments, even if the number of light emitting pixel drivers is not reduced, a light transmitting area for providing an optical path of optical sensors can be secured. Accordingly, even if a portion of the display area overlaps the optical sensors, deterioration of display quality can be reduced or prevented.

According to some embodiments, because one bias voltage line does not extend in a straight line in the first direction but includes the bypass portion that bypasses the light transmitting area, a wider light transmission area can be secured.

However, effects according to some embodiments of the present disclosure are not limited to those exemplified above and various other effects are incorporated herein.

### BRIEF DESCRIPTION OF THE DRAWINGS

These and/or other aspects will become apparent and more readily appreciated from the following description of some embodiments, taken in conjunction with the accompanying drawings in which:

FIG. 1 is a perspective view of an electronic device according to some embodiments;

FIG. 2 is an exploded perspective view of the electronic device of FIG. 1;

FIG. 3 is a plan view of a display device of FIG. 2;

FIG. 4 is a cross-sectional view taken along line A-A′ of FIG. 3;

FIG. 5 is a layout view of part B of FIG. 3;

FIG. 6 is an equivalent circuit diagram of a light emitting pixel driver in FIG. 5;

FIG. 7 is a layout view of part C of FIG. 3;

FIG. 8 is a plan view of a circuit layer in part D of FIG. 7 according to some embodiments;

FIG. 9 illustrates a first semiconductor layer, a first gate conductive layer, and a bias voltage line in the plan view of FIG. 8;

FIG. 10 is a cross-sectional view taken along line F-F′ of FIG. 8;

FIG. 11 is a plan view illustrating a first semiconductor layer, a first gate conductive layer, a bias voltage line, and a first source-drain conductive layer in part D of FIG. 7 according to some embodiments;

FIG. 12 illustrates a first semiconductor layer, a first gate conductive layer, and anode initialization voltage lines in part D of FIG. 7 according to some embodiments;

FIG. 13 is a plan view of a circuit layer in part E of FIG. 7 according to some embodiments;

FIG. 14 is a cross-sectional view taken along line G-G′ of FIG. 13;

FIG. 15 illustrates a first semiconductor layer, a first gate conductive layer, and a bias voltage line in part D of FIG. 7 according to some embodiments;

FIG. 16 is a plan view illustrating a first semiconductor layer, a first gate conductive layer, and a third gate conductive layer in part D′ of FIG. 7 according to some embodiments;

FIG. 17 is a plan view illustrating a first gate conductive layer, a second gate conductive layer, a second semiconductor layer, and a third gate conductive layer in part E of FIG. 7 according to some embodiments;

FIG. 18 is a plan view illustrating a first gate conductive layer, a second gate conductive layer, a second semiconductor layer, and a third gate conductive layer in part E of FIG. 7 according to some embodiments;

FIG. 19 is a plan view illustrating a first gate conductive layer, a second gate conductive layer, a second semiconductor layer, and a third gate conductive layer in part E of FIG. 7 according to some embodiments;

FIG. 20 is a plan view illustrating a first semiconductor layer and a second semiconductor layer of each of a first light emitting pixel driver, a second light emitting pixel driver, a third light emitting pixel driver, and a fourth light emitting pixel driver according to some embodiments; and

FIG. 21 is a plan view illustrating a first semiconductor layer and a second semiconductor layer of each of a first light emitting pixel driver, a second light emitting pixel driver, a third light emitting pixel driver, and a fourth light emitting pixel driver according to some embodiments.

The above and other aspects and features of the present disclosure will be more clearly understood from the following detailed description of the illustrative, non-limiting embodiments with reference to the accompanying drawings.

### DETAILED DESCRIPTION

Embodiments of the present disclosure will now be described more fully hereinafter with reference to the accompanying drawings. Some embodiments may, however, be provided in different forms and should not be construed as limiting. The same reference numbers indicate the same components throughout the present disclosure. In the accompanying figures, the thickness of layers and regions may be exaggerated for clarity.

Some of the parts that are not associated with the description may not be provided in order to describe embodiments of the present disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and/or vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the spirit and scope of the present disclosure herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which the present disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments will be described with reference to the accompanying drawings.

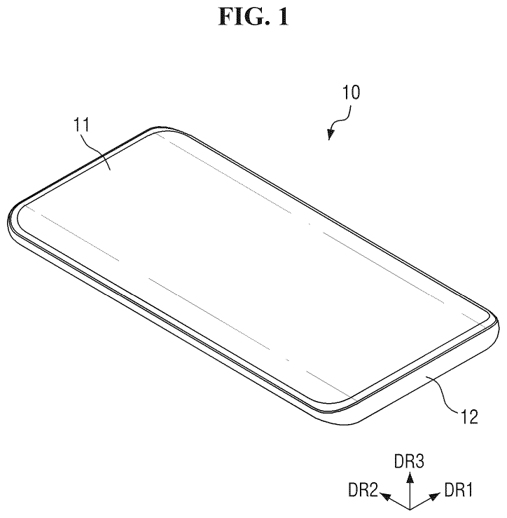

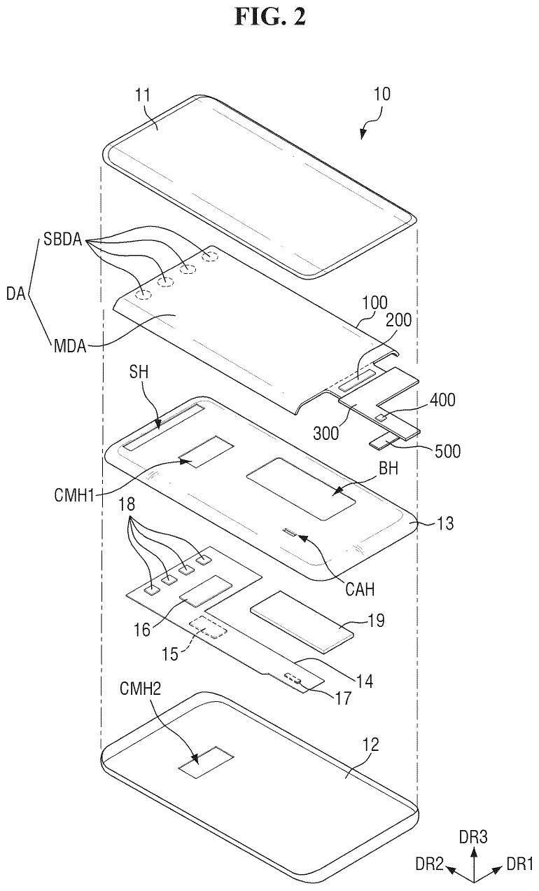

FIG. 1 is a perspective view of an electronic device 10 according to some embodiments. FIG. 2 is an exploded perspective view of the electronic device 10 of FIG. 1.

Referring to FIG. 1, the electronic device 10 according to some embodiments is a device that has a function of displaying an image in a display area. The electronic device 10 may be portable. For example, the electronic device 10 may be a portable electronic device, such as a mobile phone, a smartphone, a tablet personal computer (PC), a smart watch, a watch phone, a mobile communication terminal, an electronic notebook, an electronic book, a portable multimedia player (PMP), a navigation device, or an ultra-mobile PC (UMPC).

However, the electronic device 10 according to some embodiments is not limited to portable electronic devices and may also be a large-sized device, such as a television, a notebook computer, a monitor, a billboard, or an Internet of things (IoT) device.

The electronic device 10 may include a cover window 11 and a bottom cover 12 provided as a housing to protect a display device 100 (see FIG. 2).

Referring to FIG. 2, the electronic device 10 according to some embodiments may further include the display device 100, a bracket 13, one or more optical devices 18, and a main circuit board 14 accommodated between the cover window 11 and the bottom cover 12.

In the following description, a first direction DR1 may be a direction parallel to short sides of the electronic device 10 in a plan view, that is, a horizontal direction of the electronic device 10. A second direction DR2 may be a direction parallel to long sides of the electronic device 10 in a plan view, that is, a vertical direction of the electronic device 10. A third direction DR3 may be a thickness direction of the electronic device 10.

The electronic device 10 may have a rectangular shape in a plan view. For example, the electronic device 10 may be shaped like a rectangular plane having short sides in the first direction DR1 and long sides in the second direction DR2. Each corner where a short side extending in the first direction DR1 meets a long side extending in the second direction DR2 may be rounded with a preset curvature or may be right-angled. The planar shape of the electronic device 10 is not limited to the rectangular shape but may also be other polygonal shapes, a circular shape, or an oval shape.

The electronic device 10 may include a display surface on which a display area DA where an image is displayed.

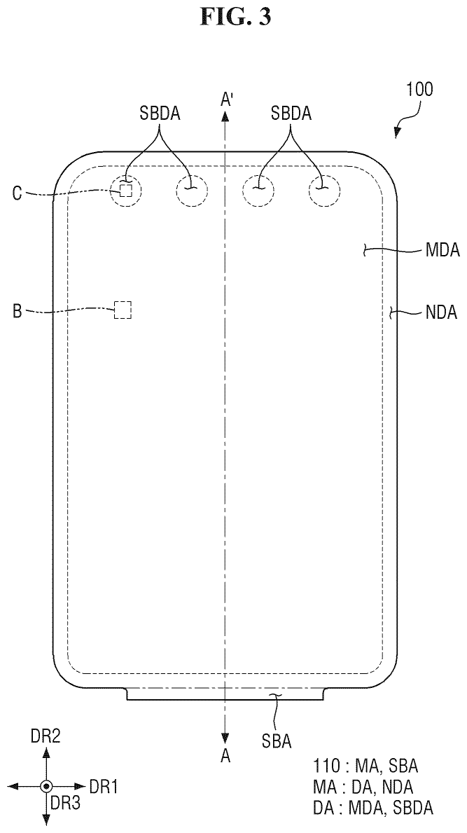

The display device 100 may include the display area DA emitting light to the display surface of the electronic device 10 and a non-display area NDA disposed around the display area DA. In addition, the display device 100 may further include a sub-area SBA (see FIG. 3) protruding from a portion of the non-display area NDA (see FIG. 3) adjacent to a short edge of the display area DA.

The display device 100 may further include a display driving circuit 200 disposed in the sub-area SBA (see FIG. 3), a display circuit board 300 fastened to an edge of the sub-area SBA (see FIG. 3), a touch driving circuit 400 mounted on the display circuit board 300, and a cable 500 extending from a side of the display circuit board 300.

The display area DA may include a main display area MDA disposed in most of the display area DA and one or more sub-display areas SBDA surrounded by the main display area MDA and overlapping the optical devices 18.

The cover window 11 may be disposed on the display device 100. Therefore, a surface of the display device 100 from which light is emitted may be covered by the cover window 11.

The cover window 11 may protect an upper surface of the display device 100.

The cover window 11 may include a light transmitting portion, which is transparent, and a light blocking portion, which is opaque.

The light transmitting portion may overlap the display area DA of the display device 100 in the third direction DR3, and the light blocking portion may overlap the non-display area NDA of the display device 100 in the third direction DR3.

The cover window 11 may include an upper surface portion that forms an upper surface of the electronic device 10, a left side surface portion that forms a left side surface of the electronic device 10, and a right side surface portion that forms a right side surface of the electronic device 10. The left side surface portion of the cover window 11 may extend from a left side of the upper surface portion, and the right side surface portion may extend from a right side of the upper surface portion.

Each of the upper surface portion, the left side surface portion, and the right side surface portion of the cover window 11 may include a light transmitting portion and a light blocking portion.

The light transmitting portion of the cover window 11 may be disposed in most of each of the upper surface portion, the left side surface portion, and the right side surface portion of the cover window 11.

The light blocking portion of the cover window 11 may be disposed at an upper edge and a lower edge of the upper surface portion of the cover window 11, at an upper edge, a left edge and a lower edge of the left side surface portion of the cover window 11, and at an upper edge, a right edge and a lower edge of the right side surface portion of the cover window 11.

The bracket 13 may be disposed under the display device 100.

The bracket 13 may include plastic, metal, or both plastic and metal. The bracket 13 may include a first camera hole CMH1 into which a camera device 16 is inserted, a battery hole BH into which a battery 19 is fixed, a light transmission hole SH into which the optical devices 18 are inserted, and a cable hole CAH through which the cable 500 connected to the display circuit board 300 passes.

The main circuit board 14 and the battery 19 may be disposed under the bracket 13. The main circuit board 14 may be a printed circuit board or a flexible printed circuit board.

A main processor 15, the camera device 16, a main connector 17, and the optical devices 18 may be mounted on the main circuit board 14.

The camera device 16 may be disposed on both an upper surface and a lower surface of the main circuit board 14. The main processor 15 may be disposed on the upper surface of the main circuit board 14, and the main connector 17 may be disposed on the lower surface of the main circuit board 14.

The main processor 15 may control substantially all functions of the electronic device 10.

For example, the main processor 15 may output digital video data to the display driving circuit 200 through the display circuit board 300 so that the display panel 100 can display an image. In addition, the main processor 15 may receive touch data including a user's touch coordinates from the touch driving circuit 400, determine whether the user has touched or is in proximity to the display device 100, and perform an operation corresponding to the user's touch input or proximity input. For example, the main processor 15 may execute an application or perform an operation indicated by an icon touched by the user.

The main processor 15 may be an application processor, a central processing unit, a system chip formed as an integrated circuit, or the like.

The camera device 16 may process an image frame, such as a still image or a moving image, obtained by an image sensor in camera mode, and may output the processed image frame to the main processor 15.

The cable 500 passing through the cable hole CAH of the bracket 13 may be connected to the main connector 17. Accordingly, the main circuit board 14 may be electrically connected to the display circuit board 300.

The optical devices 18 may include a proximity sensor, an illuminance sensor, an iris sensor, a second camera sensor, and the like.

The optical devices 18, such as the proximity sensor, the illuminance sensor, the iris sensor, and the second camera sensor, may be disposed on the upper surface of the main circuit board 14 and in the light transmission hole SH of the bracket 13.

The proximity sensor is a sensor for detecting an object located close to a front surface of the electronic device 10. The proximity sensor may include a light source, which outputs light, and a light reception unit (e.g., a light receptor), which receives light reflected by an object. The proximity sensor may generate a sensing signal corresponding to the amount of light reflected by an object. Whether there is an object located close to the front surface of the electronic device 10 may be determined based on the sensing signal of the proximity sensor.

The illuminance sensor is a sensor for detecting the brightness of the front surface of the electronic device 10. The illuminance sensor may include a resistor whose resistance value (e.g., resistance) varies according to the brightness of incident light.

The iris sensor is a sensor for photographing a user's iris. Whether the user is a pre-registered user may be verified based on whether an image captured by the iris sensor is substantially identical to an iris image pre-stored in a memory.

The second camera sensor may process an image frame, such as a still image or a moving image, obtained by an image sensor and may output the processed image frame to the main processor 15. The second camera sensor may be a CMOS image sensor or a CCD sensor. The number of pixels of the second camera sensor may be less than the number of pixels of the camera device 16, and the size of the second camera sensor may be smaller than the size of the camera device 16.

The battery 19 may be spaced apart from the main circuit board 14. For example, the battery 19 may not overlap the main circuit board 14 in the third direction DR3. The battery 19 may be disposed in the battery hole BH of the bracket 13 in the third direction DR3.

In addition, the main circuit board 14 may further include a mobile communication module that can transmit and receive wireless signals to and from at least one of a base station, an external terminal, and a server over a mobile communication network. The wireless signals may include voice signals, video call signals, or various types of data resulting from transmission/reception of text/multimedia messages.

The bottom cover 12 may be disposed under the main circuit board 14 and the battery 19. The bottom cover 12 may be fastened and fixed to the bracket 13. The bottom cover 12 may form an upper side surface, a lower side surface, and a lower surface of the electronic device 10. The bottom cover 12 may include plastic, metal, or both plastic and metal.

The bottom cover 12 may include a second camera hole CMH2 exposing a lower surface of the camera device 16.

However, the positions of the light transmission hole SH, the first camera hole CMH1, and the second camera hole CMH2 are not limited to those illustrated in FIG. 2.

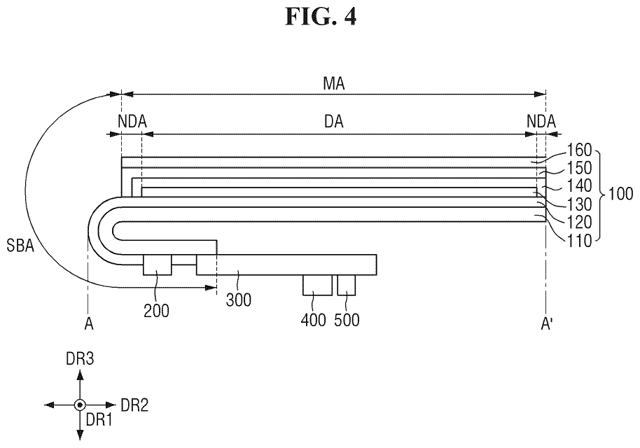

FIG. 3 is a plan view of the display device 100 of FIG. 2. FIG. 4 is a cross-sectional view taken along line A-A′ of FIG. 3.

Referring to FIG. 3, a substrate 110 of the display device 100 may include the display area DA and the non-display area NDA disposed on the display surface and the sub-area SBA protruding from a side of the non-display area NDA.

The display area DA may be disposed on most of the display surface. The display area DA may be disposed in the center of the display surface.

The display area DA may include the main display area MDA disposed in most of the display area DA and one or more sub-display areas SBDA surrounded by the main display area MDA.

The sub-display areas SBDA may overlap the optical devices 18 (see FIG. 2).

The non-display area NDA may be disposed outside the display area DA. The non-display area NDA may be an edge area of the display surface.

The sub-area SBA may protrude in the second direction DR2 from a portion of the non-display area NDA adjacent to a short side of the display area DA.

As a portion of the sub-area SBA is bent, another portion of the sub-area SBA may be overlapped by the display area DA and the non-display area NDA in the third direction DR3.

The display device 100 may include an upper surface portion facing the upper surface portion of the cover window 11, a left side surface portion facing the left side surface portion of the cover window 11, and a right side surface portion facing the right side surface portion of the cover window 11. The left side surface portion of the display device 100 may extend from a left side of the upper surface portion, and the right side surface portion may extend from a right side of the upper surface portion.

Each of the upper surface portion, the left side surface portion, and the right side surface portion of the display device 100 may include the display area DA and/or the non-display area NDA.

The display area DA may be disposed on most of the upper surface portion, the left side surface portion, and/or the right side surface portion of the display device 100.

The non-display area NDA may be disposed at edges of a main area MA to surround the display area DA.

The sub-area SBA may be an area protruding from the non-display area NDA of the main area MA to one side in the second direction DR2.

As a portion of the sub-area SBA is bent, another portion of the sub-area SBA may be disposed on a rear surface of the display device 100.

FIGS. 3 and 4 illustrate the display device 100 in which a portion of the sub-area SBA is bent.

Referring to FIG. 4, the display device 100 according to some embodiments may include the substrate 110, a circuit layer 120 disposed on the substrate 110, and an element layer 130 disposed on the circuit layer 120.

The display device 100 according to some embodiments may further include a sealing layer 140 disposed on the element layer 130 and a touch sensor layer 150 disposed on the sealing layer 140.

In addition, the display device 100 according to some embodiments may further include a polarizing layer 160 disposed on the touch sensor layer 150 to reduce reflection of external light.

The substrate 110 may be made of an insulating material, such as polymer resin. For example, the substrate 110 may be made of polyimide. The substrate 110 may be a flexible substrate that can be bent, folded, rolled, etc.

In some embodiments, the substrate 110 may be made of an insulating material, such as glass.

The substrate 110 may include the main area MA and the sub-area SBA. The main area MA may include the display area DA and the non-display area NDA.

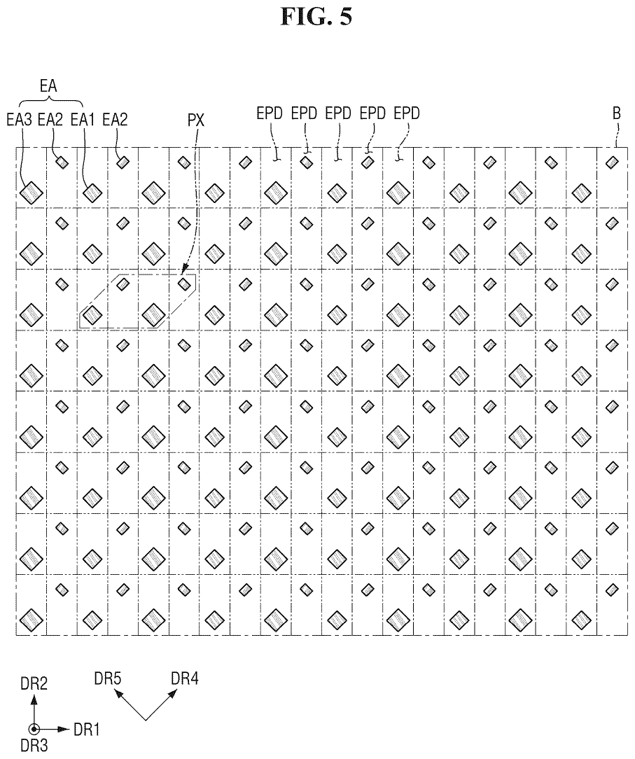

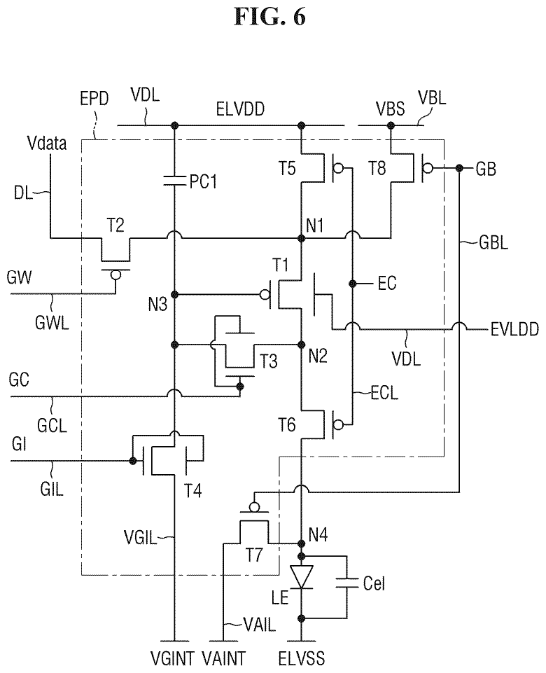

The element layer 130 may include light emitting elements LE (see FIG. 6) disposed in emission areas EA (see FIG. 5).

The circuit layer 120 may include light emitting pixel drivers EPD (see FIG. 5) electrically connected to the light emitting elements LE (see FIG. 6) of the element layer 130.

The sealing layer 140 may cover the element layer 130 and extend to the non-display area NDA to contact the circuit layer 120. The sealing layer 140 may include a structure in which two or more inorganic layers and at least one organic layer are alternately stacked.

The touch sensor layer 150 may be disposed on the sealing layer 140 and may correspond to the main area MA. The touch sensor layer 150 may include touch electrodes for detecting a touch of a person or object.

The polarizing layer 160 may block or reduce external light reflected from the touch sensor layer 150, the sealing layer 140, the element layer 130, the circuit layer 120, and/or interfaces thereof to reduce or prevent a reduction in image visibility due to reflection of the external light.

The cover window 11 of the electronic device 10 may be disposed on the polarizing layer 160. The cover window 11 may be attached onto the polarizing layer 160 by a transparent adhesive member such as an optically clear adhesive (OCA) film or an optically clear resin (OCR).

The cover window 11 may be an inorganic material, such as glass, or may be an organic material, such as a plastic or polymer material.

The cover window 11 may protect the touch sensor layer 150, the sealing layer 140, the element layer 130, and the circuit layer 120 from electrical and physical shock on the display surface.

FIG. 5 is a layout view of part B of FIG. 3.

Referring to FIG. 5, the display area DA of the display device 100 according to some embodiments may include the emission areas EA. In addition, the display area DA may further include a non-emission area disposed in a space between the emission areas EA.

The light emitting pixel drivers EPD respectively corresponding to the emission areas EA may be arranged side by side with each other in the display area DA in the first direction DR1 and the second direction DR2. The light emitting pixel drivers EPD may be electrically connected to the light emitting elements LE (see FIG. 6) of the element layer 130 in the emission areas EA, respectively.

The emission areas EA may have a rhombic planar shape or a rectangular planar shape. However, this is only an example, and the planar shape of the emission areas EA according to some embodiments is not limited to that illustrated in FIG. 5. For example, the emission areas EA may also have a polygonal shape, such as a quadrilateral, a pentagon, or a hexagon, or may have a circular or oval planar shape including a curved edge.

The emission areas EA may include first emission areas EA1 that emit light of a first color in a preset wavelength band, second emission areas EA2 that emit light of a second color in a wavelength band lower than that of the first color, and third emission areas EA3 that emit light of a third color in a wavelength band lower than that of the second color.

For example, the first color may be red in a wavelength band of about 600 nm to about 750 nm. The second color may be green in a wavelength band of about 480 nm to about 560 nm. The third color may be blue in a wavelength band of about 370 nm to about 460 nm.

The first emission areas EA1 and the third emission areas EA3 may be alternately arranged in at least one of the first direction DR1 and the second direction DR2.

The second emission areas EA2 may be arranged side-by-side with each other in at least one of the first direction DR1 and the second direction DR2.

In addition, the second emission areas EA2 may neighbor the first emission areas EA1 and the third emission areas EA3 in diagonal directions DR4 and DR5 crossing the first direction DR1 and the second direction DR2.

Pixels PX that display respective luminances and colors may be provided by the first emission areas EA1, the second emission areas EA2, and the third emission areas EA3 adjacent to each other among the emission areas EA.

The pixels PX may be basic units that display various colors, including white, at preset luminance levels.

Each of the pixels PX may include at least one first emission area EA1, at least one second emission area EA2, and at least one third emission area EA3 adjacent to each other. Therefore, each of the pixels PX may display various colors by mixing colors of light emitted from the first through third emission areas EA1, EA2 and, EA3 adjacent to each other.

FIG. 6 is an equivalent circuit diagram of a light emitting pixel driver EPD in FIG. 5.

Referring to FIG. 6, one of the light emitting elements LE of the element layer 130 may be electrically connected between one of the light emitting pixel drivers EPD of the circuit layer 120 and second power ELVSS.

For example, an anode of a light emitting element LE may be electrically connected to a light emitting pixel driver EPD, and a cathode of the light emitting element LE may receive the second power ELVSS having a lower voltage level than first power ELVDD.

A capacitor Cel connected in parallel to the light emitting element LE may represent parasitic capacitance between the anode and the cathode.

The circuit layer 120 may further include a first power line VDL that transmits the first power ELVDD, a gate initialization voltage line VGIL that transmits gate initialization voltage VGINT, an anode initialization voltage line VAIL that transmits anode initialization voltage VAINT, and a bias voltage line VBL that transmits a bias voltage VBS.

The circuit layer 120 may further include a scan write line GWL that transmits a scan write signal GW, a scan initialization line GIL that transmits a scan initialization signal GI, an emission control line ECL that transmits an emission control signal EC, a gate control line GCL that transmits a gate control signal GC, and a bias control line GBL that transmits a bias control signal GB.

A light emitting pixel driver EPD of the circuit layer 120 may include a first transistor T1 that generates a driving current for driving the light emitting element LE, two or more transistors T2 through T8 electrically connected to the first transistor T1, and at least one capacitor PC1.

The first transistor T1 may be connected in series to the light emitting element LE between the first power ELVDD and the second power ELVSS.

The first transistor T1 may be electrically connected between a first node N1 and a second node N2. The first node N1 is electrically connected to a first electrode (e.g., a source electrode) of the first transistor T1. The second node N2 is electrically connected to a second electrode (e.g., a drain electrode) of the first transistor T1.

The first electrode (e.g., the source electrode) of the first transistor T1 may be electrically connected to the first power line VDL through a fifth transistor T5. In addition, the second electrode (e.g., the drain electrode) of the first transistor T1 may be electrically connected to the anode of the light emitting element LE through a sixth transistor T6.

A first pixel capacitor PC1 may be electrically connected between the first power line VDL and a third node N3. The third node N3 may be electrically connected to a gate electrode of the first transistor T1.

For example, the gate electrode of the first transistor T1 may be electrically connected to the first power line VDL through the first capacitor PC1.

Accordingly, the electric potential of the gate electrode of the first transistor T1 may be maintained at the voltage charged in the first power line VDL.

A second transistor T2 may be electrically connected between a data line DL and the first node N1.

For example, the second transistor T2 may be electrically connected between the first electrode of the first transistor T1 and the data line DL. The second transistor T2 may be turned on by the scan write signal GW of the scan write line GWL.

For example, the first electrode of the first transistor T1 may be electrically connected to the data line DL through the second transistor T2.

The fifth transistor T5 may be electrically connected between the first node N1 and the first power line VDL.

The sixth transistor T6 may be electrically connected between the second node N2 and a fourth node N4. The fourth node N4 may be electrically connected to the anode of the light emitting element LE.

For example, the fifth transistor T5 may be electrically connected between the first electrode of the first transistor T1 and the first power line VDL.

The sixth transistor T6 may be electrically connected between the second electrode of the first transistor T1 and the anode of the light emitting element LE.

The fifth transistor T5 and the sixth transistor T6 may be turned on by the emission control signal EC of the emission control line ECL.

If a data signal Vdata of the data line DL is transmitted to the first electrode of the first transistor T1 through the turned-on second transistor T2, a voltage difference between the gate electrode of the first transistor T1 and the first electrode of the first transistor T1 may be a difference voltage between the first power ELVDD and the data signal Vdata.

If the voltage difference between the gate electrode of the first transistor T1 and the first electrode of the first transistor T1, that is, a gate-source voltage difference, is equal to or greater than a threshold voltage, the first transistor T1 may be turned on. Accordingly, a drain-source current of the first transistor T1 which corresponds to the data signal Vdata may be generated.

If the fifth transistor T5 and the sixth transistor T6 are turned on, the first transistor T1 may be connected in series to the light emitting element LE between the first power line VDL and the second power line VSL. Accordingly, the drain-source current of the first transistor T1 which corresponds to the data signal Vdata may be supplied as a driving current of the light emitting element LE.

Therefore, the light emitting element LE may emit light of a luminance corresponding to the data signal Vdata.

A third transistor T3 may be electrically connected between the second node N2 and the third node N3. For example, the third transistor T3 may be electrically connected between the gate electrode of the first transistor T1 and the second electrode of the first transistor T1. The third transistor T3 may be turned on by the gate control signal GC of the gate control line GCL.

A voltage difference between the second node N2 and the third node N3 may be initialized through the turned-on third transistor T3.

A fourth transistor T4 may be electrically connected between the gate initialization voltage line VGIL and the third node N3. For example, the fourth transistor T4 may be connected between the gate electrode of the first transistor T1 and the gate initialization voltage line VGIL. The fourth transistor T4 may be turned on by the scan initialization signal GI of the scan initialization line GIL.

The electric potential of the third node N3 may be initialized through the turned-on fourth transistor T4.

The third transistor T3 and the fourth transistor T4 may be provided as N-type MOSFETs.

A seventh transistor T7 may be electrically connected between the fourth node N4 and the anode initialization voltage line VAIL. For example, the seventh transistor T7 may be electrically connected between the anode of the light emitting element LE and the anode initialization voltage line VAIL. The seventh transistor T7 may be turned on by the bias control signal GB of the bias control line GBL.

The electric potential of the fourth node N4 may be initialized through the turned-on seventh transistor T7.

An eighth transistor T8 may be electrically connected between the first node N1 and the bias voltage line VBL. For example, the eighth transistor T8 may be electrically connected between the first electrode of the first transistor T1 and the bias voltage line VBL. The eighth transistor T8 may be turned on by the bias control signal GB of the bias control line GBL.

The electric potential of the first node N1 may be initialized through the turned-on eighth transistor T8.

The transistors T1, T2, T5, T6, T7, and T8 may be provided as P-type MOSFETS.

For example, among the first through eighth transistors T1 through T8 included in the light emitting pixel driver EPD, the third transistor T3 and the fourth transistor T4 may be provided as N-type MOSFETs, and the transistors T1, T2, T5, T6, T7, and T8 may be provided as P-type MOSFETs.

Therefore, according to some embodiments, the circuit layer 120 (see FIG. 4) may include a first semiconductor layer and a second semiconductor layer.

The first semiconductor layer may include a channel portion, a first electrode portion, and a second electrode portion of each of the first transistor T1, the second transistor T2, the fifth transistor T5, the sixth transistor T6, the seventh transistor T7, and the eighth transistor T8. In each of the first transistor T1, the second transistor T2, the fifth transistor T5, the sixth transistor T6, the seventh transistor T7, and the eighth transistor T8, the channel portion may overlap a gate electrode. In addition, in each of the first transistor T1, the second transistor T2, the fifth transistor T5, the sixth transistor T6, the seventh transistor T7, and the eighth transistor T8, the first electrode portion and the second electrode portion may be connected to both ends of the channel portion. The first electrode portion may become a first electrode, and the second electrode portion may become a second electrode.

The second semiconductor layer may include a channel portion, a first electrode portion, and a second electrode portion of each of the third transistor T3 and the fourth transistor T4. In each of the third transistor T3 and the fourth transistor T4, the channel portion may be disposed between a first gate electrode and a second gate electrode overlapping each other and may overlap the first gate electrode and the second gate electrode. In each of the third transistor T3 and the fourth transistor T4, the first electrode portion and the second electrode portion may be connected to both ends of the channel portion. The first electrode portion may become a first electrode, and the second electrode portion may become a second electrode.

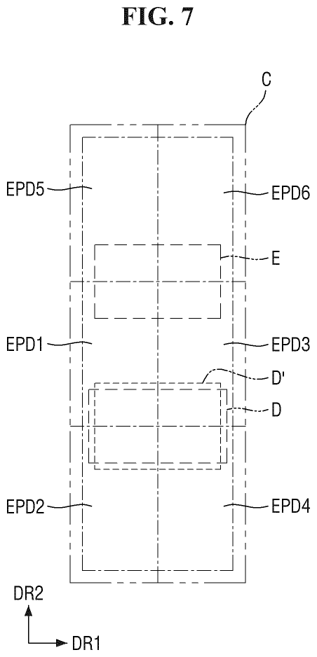

FIG. 7 is a layout view of part C of FIG. 3.

Referring to FIG. 7, the light emitting pixel drivers EPD of the circuit layer 120 of the display device 100 according to some embodiments may include a first light emitting pixel driver EPD1 and a second light emitting pixel driver EPD2 neighboring each other in the second direction DR2.

The second light emitting pixel driver EPD2 may be adjacent to a side of the first light emitting pixel driver EPD1 in the second direction DR2.

According to some embodiments, the light emitting pixel drivers EPD may further include a third light emitting pixel driver EPD3 neighboring the first light emitting pixel driver EPD1 in the first direction DR1 and a fourth light emitting pixel driver EPD4 neighboring the second light emitting pixel driver EPD2 in the first direction DR1.

According to some embodiments, the light emitting pixel drivers EPD may further include a fifth light emitting pixel driver EPD5 adjacent to the other side of the first light emitting pixel driver EPD1 in the second direction DR2.

In addition, the light emitting pixel drivers EPD may further include a sixth light emitting pixel driver EPD6 neighboring the fifth light emitting pixel driver EPD5 in the first direction DR1.

FIG. 7 illustrates the first through sixth light emitting pixel drivers EPD1 through EPD6 arranged in a matrix in a portion of a sub-display area SBDA of the display area DA. However, this is only an example, and embodiments are not limited to the illustrations in FIGS. 3 and 7. For example, the first through sixth light emitting pixel drivers EPD1 through EPD6 may also be arranged in a matrix in a portion of the main display area MDA.

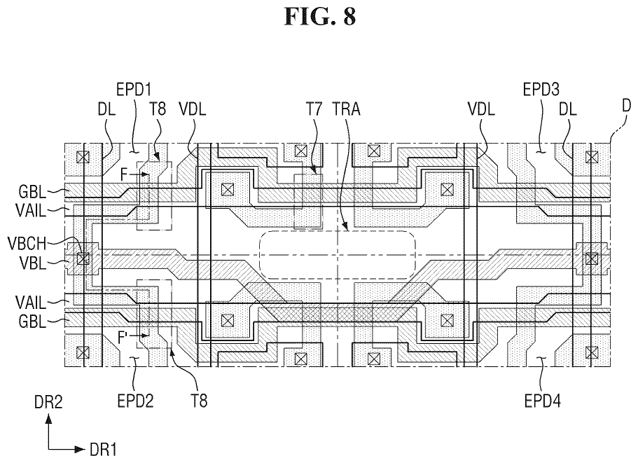

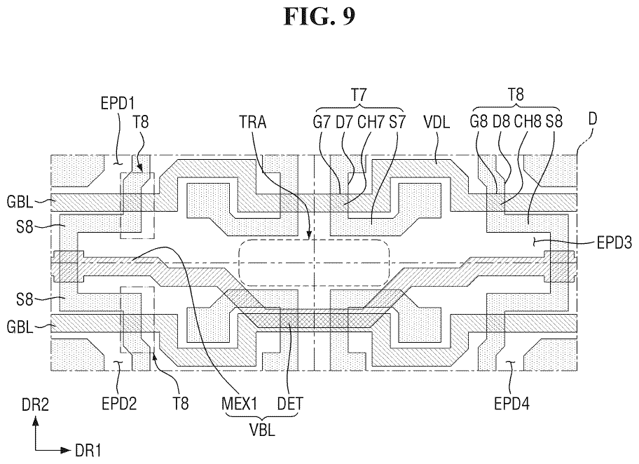

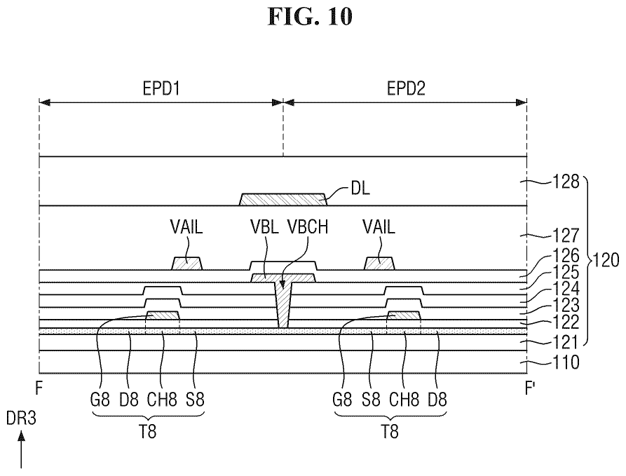

FIG. 8 is a plan view of the circuit layer 120 in part D of FIG. 7 according to some embodiments. FIG. 9 illustrates a first semiconductor layer, a first gate conductive layer, and a bias voltage line VBL in the plan view of FIG. 8. FIG. 10 is a cross-sectional view taken along line F-F′ of FIG. 8.

As illustrated in FIG. 6, the circuit layer 120 may include the bias voltage line VBL that transmits the bias voltage VBS to the light emitting pixel drivers EPD.

As illustrated in FIGS. 8, 9 and 10, according to some embodiments, the first light emitting pixel driver EPD1 and the second light emitting pixel driver EPD2 neighboring each other in the second direction DR2 may be electrically connected to one bias voltage line VBL disposed adjacent to a boundary between the first light emitting pixel driver EPD1 and the second light emitting pixel driver EPD2.

One bias voltage line VBL may extend in the first direction DR1 and may be disposed adjacent to a boundary between the third light emitting pixel driver EPD3 and the fourth light emitting pixel driver EPD4 neighboring the first light emitting pixel driver EPD1 and the second light emitting pixel driver EPD2 in the first direction DR1. The third light emitting pixel driver EPD3 and the fourth light emitting pixel driver EPD4 may be electrically connected to one bias voltage line VBL.

For example, the first through fourth light emitting pixel drivers EPD1 through EPD4 neighboring each other in the first direction DR1 and the second direction DR2 may share one bias voltage line VBL.

In this case, the number of bias voltage lines VBL arranged in the main area MA can be reduced by about half, compared with a structure in which two light emitting pixel drivers EPD1 and EPD2 or EPD3 and EPD4 neighboring each other in the second direction DR2 are connected to two bias voltage lines VBL.

For example, a space may be provided between two light emitting pixel drivers EPD1 and EPD2 or EPD3 and EPD4 neighboring each other in the second direction DR2. Therefore, a portion of the display area DA which includes a contact point between the first through fourth light emitting pixel drivers EPD1 through EPD4 neighboring each other in the first direction DR1 and the second direction DR2 may be provided as a light transmitting area TRA in which conductive layers are not disposed.

Because the light transmitting area TRA can provide an optical path of the display device 100, even if the optical devices 18 disposed under the display device 100 overlap the display area DA, the functions of the optical devices 18 can be executed through the light transmitting area TRA.

Therefore, in the display area DA, the resolution of the sub-display areas SBDA overlapping the optical devices 18 can be maintained the same as the resolution of the main display area MDA, thus reducing or preventing deterioration of display quality due to the arrangement of the optical devices 18.

As illustrated in FIG. 8, according to some embodiments, anode initialization voltage lines VAIL may extend in the first direction DR1. One anode initialization voltage line VAIL may overlap the first light emitting pixel driver EPD1 and the third light emitting pixel driver EPD3 neighboring each other in the first direction DR1, and another anode initialization voltage line VAIL may overlap the second light emitting pixel driver EPD2 and the fourth light emitting pixel driver EPD4 neighboring each other in the first direction DR1.

Bias control lines GBL may also extend in the first direction DR1. One bias control line GBL may overlap the first light emitting pixel driver EPD1 and the third light emitting pixel driver EPD3 neighboring each other in the first direction DR1. Another bias control line GBL may overlap the second light emitting pixel driver EPD2 and the fourth light emitting pixel driver EPD4 overlapping each other in the first direction DR1.

The anode initialization voltage lines VAIL and the bias control lines GBL may be disposed adjacent to the bias voltage line VBL in the second direction DR2.

In each of the light emitting pixel drivers EPD, a channel portion CH7 of the seventh transistor T7 and a channel portion CH8 of the eighth transistor T8 may be disposed at intersections of a bias control line GBL and the first semiconductor layer.

The seventh transistor T7 may be electrically connected to an anode initialization voltage line VAIL through an anode initialization voltage connection hole.

The eighth transistor T8 may be electrically connected to the bias voltage line VBL through a bias voltage connection hole VBCH.

Data lines DL and first power lines VDL may extend in the second direction DR2.

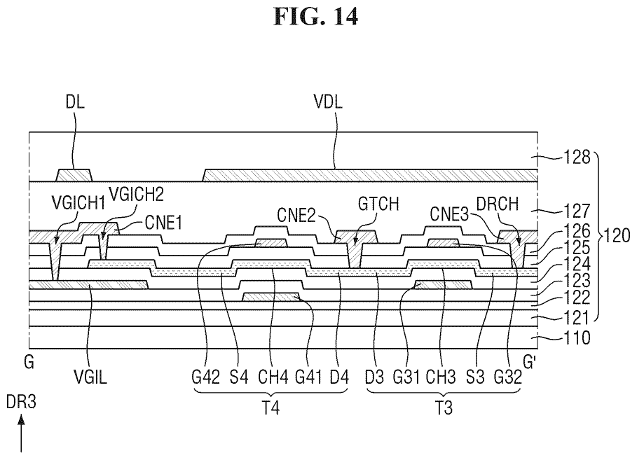

As illustrated in FIG. 10, the circuit layer 120 of the display device 100 (see FIG. 2) according to some embodiments may include the first semiconductor layer (CH8, S8, and D8) disposed on the substrate 110, a first gate insulating layer 122 covering the first semiconductor layer, the first gate conductive layer (G8 and G41 of FIG. 14) disposed on the first gate insulating layer 122, a second gate insulating layer 123 covering the first gate conductive layer, a second gate conductive layer (G31 and VGIL of FIG. 14) disposed on the second gate insulating layer 123, a first interlayer insulating layer 124 covering the second gate conductive layer, a second semiconductor layer (CH3, S3, D3, CH4, S4, and D4 of FIG. 14) disposed on the first interlayer insulating layer 124, a third gate insulating layer 125 covering the second semiconductor layer, a third gate conductive layer (VBL, G32, and G42 of FIG. 14) disposed on the third gate insulating layer 125, a second interlayer insulating layer 126 covering the third gate conductive layer, a first source-drain conductive layer (VAIL, CNE1, CNE2, and CNE3 of FIG. 14) disposed on the second interlayer insulating layer 126, a first planarization layer 127 covering the first source-drain conductive layer, a second source-drain conductive layer (DL and VDL of FIG. 14) disposed on the first planarization layer 127, and a second planarization layer 128 covering the second source-drain conductive layer.

According to some embodiments, the circuit layer 120 may further include a buffer layer 121 covering the substrate 110. In this case, the first semiconductor layer may be disposed on the buffer layer 121.

As illustrated in FIGS. 9 and 10, the seventh transistor T7 may include the channel portion CH7, a first electrode portion S7, and a second electrode portion D7 provided as the first semiconductor layer, and may include a gate electrode G7 provided as a portion of a bias control line GBL which overlaps the channel portion CH7.

The eighth transistor T8 may include the channel portion CH8, a first electrode portion S8, and a second electrode portion D8 provided as the first semiconductor layer, and may include a gate electrode G8 provided as another portion of the bias control line GBL which overlaps the channel portion CH8.

According to some embodiments, the first electrode portion S8 of the eighth transistor T8 of the first light emitting pixel driver EPD1 and the first electrode portion S8 of the eighth transistor T8 of the second light emitting pixel driver EPD2 may be connected to each other and may be electrically connected to one bias voltage line VBL through the bias voltage connection hole VBCH (see FIG. 8).

As illustrated in FIG. 10, the first semiconductor layer on the buffer layer 121 may include the channel portion CH8, the first electrode portion S8, and the second electrode portion D8 of the eighth transistor T8.

Referring to FIG. 9, the first semiconductor layer on the buffer layer 121 may further include the channel portion CH7, the first electrode portion S7, and the second electrode portion D7 of the seventh transistor T7.

Referring to FIG. 6, because the first transistor T1, the second transistor T2, the fifth transistor T5, and the sixth transistor T6 may be provided as P-type MOSFETs, like the seventh transistor T7 and the eighth transistor T8, the first semiconductor layer on the buffer layer 121 may further include a channel portion, a first electrode portion, and a second electrode portion of each of the first transistor T1, the second transistor T2, the fifth transistor T5, and the sixth transistor T6.

Referring to FIG. 10, the first gate conductive layer on the first gate insulating layer 122 may include the gate electrode G8 of the eighth transistor T8.

Referring to FIG. 9, because the gate electrode G7 of the seventh transistor T7 and the gate electrode G8 of the eighth transistor T8 are portions of a bias control line GBL, the first gate conductive layer on the first gate insulating layer 122 may include the bias control lines GBL.

The third gate conductive layer on the third gate insulating layer 125 may include the bias voltage line VBL.

The first source-drain conductive layer on the second interlayer insulating layer 126 may include the anode initialization voltage lines VAIL.

The second source-drain conductive layer on the first planarization layer 127 may include the data lines DL.

As illustrated in FIG. 9, according to some embodiments, one bias voltage line VBL may include a first main extension portion MEX1 extending in the first direction DR1 and a bypass portion DET connected to the first main extension portion MEX1 and bypassing the light transmitting area TRA.

The first main extension portion MEX1 may be disposed adjacent to the boundary between two light emitting pixel drivers EPD1 and EPD2 or EPD3 and EPD4 neighboring each other in the second direction DR2.

The bias voltage connection hole VBCH may overlap the first main extension portion MEX1.

The light transmitting area TRA may be a portion of the display area DA which includes a contact point between the first through fourth light emitting pixel drivers EPD1 through EPD4 neighboring each other in the first direction DR1 and the second direction DR2.

The bypass portion DET may be disposed in a ‘U’ shape that protrudes from the first main extension portion MEX1 to one side in the second direction DR2.

According to some embodiments, because the bias voltage line VBL includes not only the first main extension portion MEX1 but also the bypass portion DET as described above, a wider light transmitting area TRA can be provided.

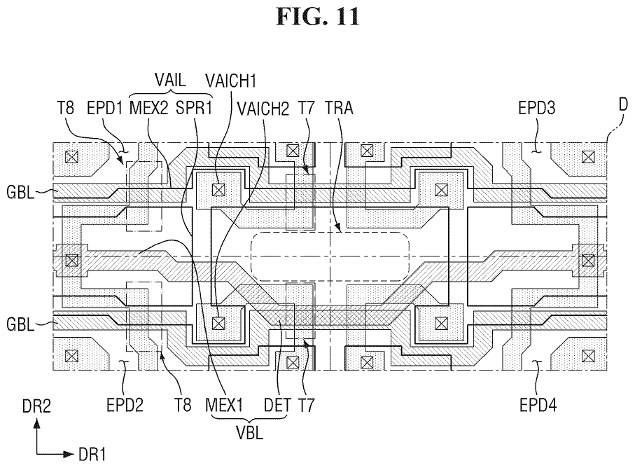

FIG. 11 is a plan view illustrating a first semiconductor layer, a first gate conductive layer, a bias voltage line VBL, and a first source-drain conductive layer in part D of FIG. 7 according to some embodiments.

A display device 100 according to some embodiments illustrated in FIG. 11 is substantially the same as that of some embodiments illustrated in FIGS. 1 through 10 except that a first light emitting pixel driver EPD1 and a second light emitting pixel driver EPD2 neighboring each other in the second direction DR2 share one anode initialization voltage line VAIL. Therefore, any redundant descriptions will be omitted below.

According to some embodiments of FIG. 11, the anode initialization voltage line VAIL may include a second main extension portion MEX2 disposed adjacent to a first main extension portion MEX1 of the bias voltage line VBL and extending in the first direction DR1 and first sub-protruding portions SPR1 protruding from the second main extension portion MEX2 and extending in the second direction DR2.

The second main extension portion MEX2 may overlap the first light emitting pixel driver EPD1.

The first sub-protruding portions SPR1 may cross the bias voltage line VBL.

An end of a first sub-protruding portion SPR1 may overlap the second light emitting pixel driver EPD2.

Accordingly, a first electrode portion S7 of a seventh transistor T7 of the first light emitting pixel driver EPD1 may be electrically connected to the anode initialization voltage line VAIL through a first anode initialization connection hole VAICH1 overlapping the second main extension portion MEX2.

In addition, a first electrode portion S7 of a seventh transistor T7 of the second light emitting pixel driver EPD2 may be electrically connected to the anode initialization voltage line VAIL through a second anode initialization connection hole VAICH2 overlapping the first sub-protruding portion SPR1.

Furthermore, because the second main extension portion MEX2 extends in the first direction DR1, a third light emitting pixel driver EPD3 neighboring the first light emitting pixel driver EPD1 in the first direction DR1 may be electrically connected to the anode initialization voltage line VAIL through a first anode initialization connection hole VAICH1, and a fourth light emitting pixel driver EPD4 neighboring the second light emitting pixel driver EPD2 in the first direction DR1 may be electrically connected to the anode initialization voltage line VAIL through a second anode initialization connection hole VAICH2.

Accordingly, according to some embodiments, because the first through fourth light emitting pixel drivers EPD1 through EPD4 neighboring each other in the first direction DR1 and the second direction DR2 share one anode initialization voltage line VAIL, the number of anode initialization voltage lines VAIL arranged in a main area MA may be reduced by about half.

Therefore, it is possible to secure a wider light transmitting area TRA, which includes a contact point between the first through fourth light emitting pixel drivers EPD1 through EPD4, according to the reduction in the number of anode initialization voltage lines VAIL, without changing the number of light emitting pixel drivers EPD.

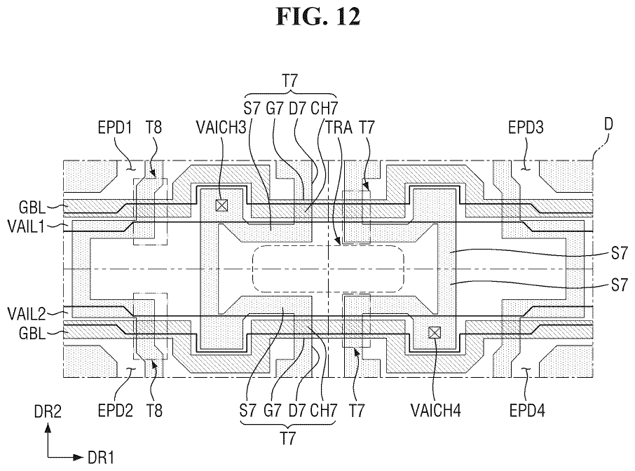

FIG. 12 illustrates a first semiconductor layer, a first gate conductive layer, and anode initialization voltage lines VAIL1 and VAIL2 in part D of FIG. 7 according to some embodiments.

A display device 100 of some embodiments illustrated in FIG. 12 is substantially the same as that of some embodiments illustrated in FIGS. 1 through 10 except that a circuit layer 120 may include a first anode initialization voltage line VAIL1 and a second anode initialization voltage line VAIL2 arranged alternately in the second direction DR2, instead of an anode initialization voltage line VAIL. Therefore, any redundant descriptions will be omitted below.

As illustrated in FIG. 5, emission areas EA may include first emission areas EA1, second emission areas EA2, and third emission areas EA3.

The first emission areas EA1, the second emission areas EA2, and the third emission areas EA3 may be arranged side by side in the second direction DR2.

The first emission areas EA1 and the third emission areas EA3 may be arranged alternately in the first direction DR1.

The second emission areas EA2 may be arranged side by side in the first direction DR1. The second emission areas EA2 may neighbor the first emission areas EA1 and the third emission areas EA3 in a fourth direction DR4 or a fifth direction DR5 which is oblique to the first direction DR1 and the second direction DR2.

Because the second emission areas EA2 have a smaller width than the first emission areas EA1 and the third emission areas EA3, if light emitting elements of the second emission areas EA2 are initialized to substantially the same voltage level as light emitting elements of the first emission areas EA1 and the third emission areas EA3, it may be difficult to display a luminance corresponding to a data signal Vdata.

Therefore, according to some embodiments of FIG. 12, the circuit layer 120 may include the first anode initialization voltage line VAIL1 that transmits a first anode initialization voltage for initializing the light emitting elements of the first and third emission areas EA1 and EA3 and the second anode initialization voltage line VAIL2 that transmits a second anode initialization voltage for initializing the light emitting elements of the second emission areas EA2.

A voltage level of the second anode initialization voltage may be different from a voltage level of the first anode initialization voltage.

For example, each of a first light emitting pixel driver EPD1 and a second light emitting pixel driver EPD2 may be electrically connected to a light emitting element LE of one of the first and third emission areas EA1 and EA3.

Each of a third light emitting pixel driver EPD3 and a fourth light emitting pixel driver EPD4 may be electrically connected to a light emitting element LE of a second emission area EA2.

According to some embodiments of FIG. 12, the first anode initialization voltage line VAIL1 may extend in the first direction DR1 and may be disposed adjacent to a side of the bias control line GBL in the second direction DR2.

The second anode initialization voltage line VAIL2 may extend in the first direction DR1 and may be disposed adjacent to the other side of the bias voltage line VBL in the second direction DR2.

For example, the first anode initialization voltage line VAIL1 may overlap the first light emitting pixel driver EPD1 and the third light emitting pixel driver EPD3, and the second anode initialization voltage line VAIL2 may overlap the second light emitting pixel driver EPD2 and the fourth light emitting pixel driver EPD4.

According to some embodiments illustrated in FIG. 12, a first electrode portion S7 of a seventh transistor T7 of the first light emitting pixel driver EPD1 and a first electrode portion S7 of a seventh transistor T7 of the second light emitting pixel driver EPD2 may be connected to each other and may be electrically connected to the first anode initialization voltage line VAIL1 through a third anode initialization connection hole VAICH3.

Likewise, a first electrode portion S7 of a seventh transistor T7 of the third light emitting pixel driver EPD3 and a first electrode portion S7 of a seventh transistor T7 of the fourth light emitting pixel driver EPD4 may be connected to each other and may be electrically connected to the second anode initialization voltage line VAIL2 through a fourth anode initialization connection hole VAICH4.

In this case, even if the circuit layer 120 includes the first anode initialization voltage line VAIL1 and the second anode initialization voltage line VAIL2 rather than a single anode initialization voltage line VAIL, the number of lines that transmit an anode initialization voltage may not be doubled, thus reducing or preventing a reduction in the width of a light transmitting area TRA.

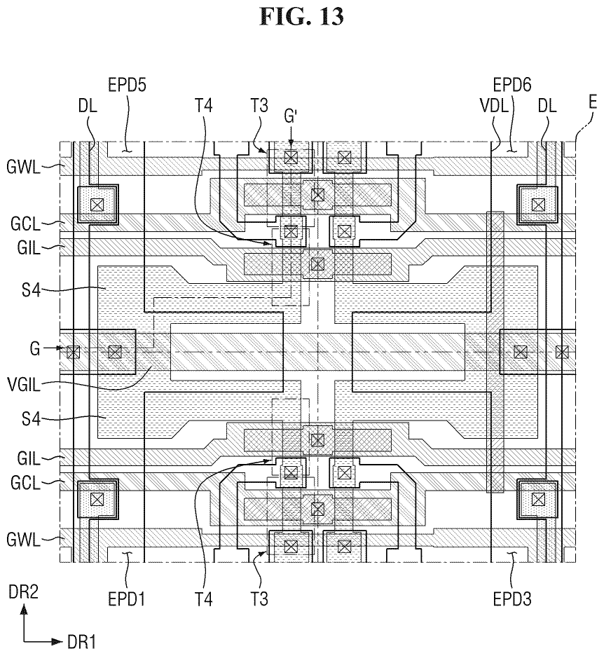

FIG. 13 is a plan view of a circuit layer 120 in part E of FIG. 7 according to some embodiments. FIG. 14 is a cross-sectional view taken along line G-G′ of FIG. 13.

As illustrated in FIG. 13, according to some embodiments, a first light emitting pixel driver EPD1 and a fifth light emitting pixel driver EPD5 neighboring each other in the second direction DR2 may be electrically connected to one gate initialization voltage line VGIL disposed adjacent to a boundary between the first light emitting pixel driver EPD1 and the fifth light emitting pixel driver EPD5. The first light emitting pixel driver EPD1 may neighbor a second light emitting pixel driver EPD2 on one side in the second direction DR2 (a lower side in FIG. 7) and may neighbor the fifth light emitting pixel driver EPD5 on the other side in the second direction DR2 (an upper side in FIG. 7).

One gate initialization voltage line VGIL may extend in the first direction DR1 and may be disposed adjacent to a boundary between a third light emitting pixel driver EPD3 and a sixth light emitting pixel driver EPD6. The third light emitting pixel driver EPD3 and the sixth light emitting pixel driver EPD6 may be electrically connected to one gate initialization voltage line VGIL.

For example, the fifth light emitting pixel driver EPD5, the first light emitting pixel driver EPD1, the sixth light emitting pixel driver EPD6, and the third light emitting pixel driver EPD3, neighboring each other in the first direction DR1 and the second direction DR2, may share one gate initialization voltage line VGIL.

In this case, the number of gate initialization voltage lines VGIL arranged in a main area MA can be reduced by about half compared with a structure in which the two light emitting pixel drivers EPD1 and EPD5 neighboring each other in the second direction DR2 are connected to two gate initialization voltage lines VGIL.

Therefore, it is possible to secure a wider light transmitting area TRA in a display area DA according to the reduction in the number of gate initialization voltage lines VGIL.

As illustrated in FIG. 13, according to some embodiments, scan write lines GWL, gate control lines GCL, and scan initialization lines GIL may extend in the first direction DR1 and may be sequentially further away from the gate initialization voltage line VGIL.

As illustrated in FIGS. 13 and 14, in each light emitting pixel driver EPD, a channel portion CH3 of a third transistor T3 may be disposed at an intersection of a second semiconductor layer on a first interlayer insulating layer 124 and a gate control line GCL.

The third transistor T3 may include the channel portion CH3, a first electrode portion S3 and a second electrode portion D3, which are provided as the second semiconductor layer on the first interlayer insulating layer 124, a first gate electrode G31, which is a portion of a gate control line GCL and provided as a second gate conductive layer on a second gate insulating layer 123, and a second gate electrode G32, which is provided as a third gate conductive layer on a third gate insulating layer 125.

In each light emitting pixel driver EPD, a channel portion CH4 of a fourth transistor T4 may be disposed at an intersection of the second semiconductor layer on the first interlayer insulating layer 124 and a scan initialization line GIL.

The fourth transistor T4 may include the channel portion CH4, a first electrode portion S4 and a second electrode portion D4, which are provided as the second semiconductor layer on the first interlayer insulating layer 124, a first gate electrode G41, which is a portion of a scan initialization line GIL and provided as a first gate conductive layer on a first gate insulating layer 122, and a second gate electrode G42, which is provided as the third gate conductive layer on the third gate insulating layer 125.

As illustrated in FIG. 14, the third gate conductive layer on the third gate insulating layer 125 may include the gate initialization voltage line VGIL.

A first source-drain conductive layer on a second interlayer insulating layer 126 may include a first connection electrode CNE1, a second connection electrode CNE2, and a third connection electrode CNE3.

As illustrated in FIG. 13, according to some embodiments, the first electrode portion S4 of the fourth transistor T4 of the first light emitting pixel driver EPD1 and the first electrode portion S4 of the fourth transistor T4 of the fifth light emitting pixel driver EPD5 may be connected to each other and may be electrically connected to one gate initialization voltage line VGIL.

For example, the gate initialization voltage line VGIL may be electrically connected to the first electrode portion S4 of the fourth transistor T4 through the first connection electrode CNE1.

The first connection electrode CNE1 may be electrically connected to the gate initialization voltage line VGIL through a first gate initialization connection hole VGICH1 and may be electrically connected to the first electrode portion S4 of the fourth transistor T4 through a second gate initialization connection hole VGICH2.

The second electrode portion D3 of the third transistor T3 and the second electrode portion D4 of the fourth transistor T4 may be connected to each other and may be electrically connected to a gate electrode of a first transistor T1 through the second connection electrode CNE2. For example, the second connection electrode CNE2 may correspond to a third node N3 (see FIG. 6).

The second connection electrode CNE2 may be electrically connected to the second electrode portion D4 of the fourth transistor T4 through a gate connection hole GTCH.

The first electrode portion S3 of the third transistor T3 may be electrically connected to a second electrode of the first transistor T1 through the third connection electrode CNE3. For example, the third connection electrode CNE3 may correspond to a second node N2 (see FIG. 6).

The third connection electrode CNE3 may be electrically connected to the second electrode portion D4 of the fourth transistor T4 through a drain connection hole DRCH.

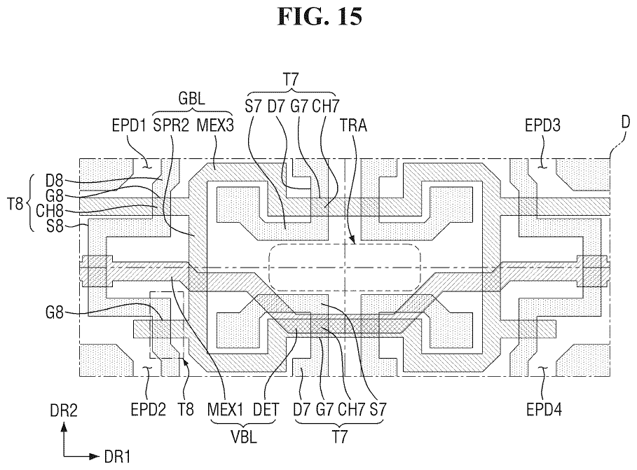

FIG. 15 illustrates a first semiconductor layer, a first gate conductive layer, and a bias voltage line VBL in part D of FIG. 7 according to some embodiments.

A display device 100 of some embodiments illustrated in FIG. 15 is substantially the same as those of some embodiments illustrated in FIGS. 1 through 14 except that a first light emitting pixel driver EPD1 and a second light emitting pixel driver EPD2 neighboring each other in the second direction DR2 share one bias control line GBL. Therefore, redundant descriptions will be omitted below.

As described with reference to FIG. 10, the first gate conductive layer on the first gate insulating layer 122 may include the bias control lines GBL that transmit bias control signals GB to light emitting pixel drivers EPD.

According to some embodiments of FIG. 15, the bias control line GBL may include a third main extension portion MEX3 disposed adjacent to a first main extension portion MEX1 of the bias voltage line VBL and extending in the first direction DR1 and second sub-protruding portions SPR2 protruding from the third main extension portion MEX3 to extend in the second direction DR2 and crossing the bias voltage line VBL.

The third main extension portion MEX3 may overlap the first light emitting pixel driver EPD1.

An end of a second sub-protruding portion SPR2 may overlap the second light emitting pixel driver EPD2.

The second sub-protruding portion SPR2 overlapping the second light emitting pixel driver EPD2 and a second sub-protruding portion SPR2 overlapping a fourth light emitting pixel driver EPD4 may extend toward each other in the first direction DR1 and may be connected to each other.

For example, a gate electrode G7 of a seventh transistor T7 of the first light emitting pixel driver EPD1, a gate electrode G8 of an eighth transistor T8 of the first light emitting pixel driver EPD1, a gate electrode G7 of a seventh transistor G7 of a third light emitting pixel driver EPD3, and a gate electrode G8 of an eighth transistor T8 of the third light emitting pixel driver EPD3 may be provided as portions of the third main extension portion MEX3 and may be connected to each other.

A gate electrode G7 of a seventh transistor T7 of the second light emitting pixel driver EPD2, a gate electrode G8 of an eighth transistor T8 of the second light emitting pixel driver EPD2, a gate electrode G7 of a seventh transistor T7 of the fourth light emitting pixel driver EPD4, and a gate electrode G8 of an eighth transistor T8 of the fourth light emitting pixel driver EPD4 may be provided as portions of extension portions of the second sub-protruding portions SPR2 in the first direction DR1 and may be connected to each other.

In this case, because the first light emitting pixel driver EPD1 and the second light emitting pixel driver EPD2 neighboring each other in the second direction DR2 share one bias control line GBL, the number of bias control lines GBL arranged in a main area MA can be reduced by about half.

Therefore, it is possible to secure wider light transmitting areas TRA in a display area DA according to the reduction in the number of bias control lines GBL without changing the number of light emitting pixel drivers EPD.

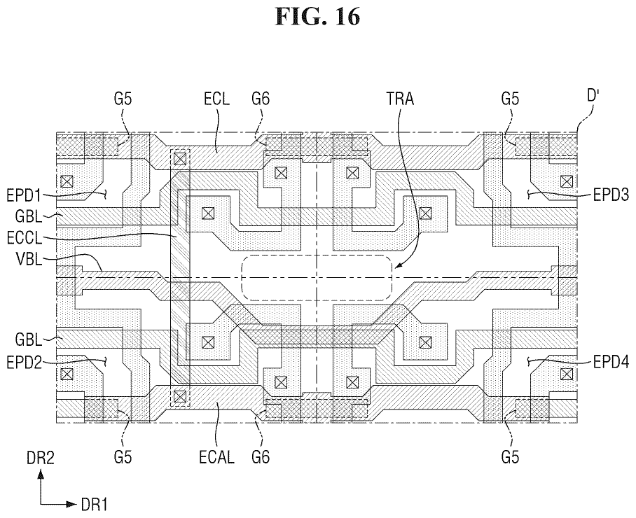

FIG. 16 is a plan view illustrating a first semiconductor layer, a first gate conductive layer, and a third gate conductive layer in part D′ of FIG. 7 according to some embodiments.

A display device 100 of some embodiments illustrated in FIG. 16 is substantially the same as those of some embodiments illustrated in FIGS. 1 through 15 except that a first light emitting pixel driver EPD1 and a second light emitting pixel driver EPD2 neighboring each other in the second direction DR2 share one emission control line ECL. Therefore, redundant descriptions will be omitted below.

Referring to FIGS. 16 and 12, gate electrodes G5 of fifth transistors T5 and gate electrodes G6 of sixth transistors T6 may be disposed in the same layer as bias control lines GBL.

For example, the first gate conductive layer on a first gate insulating layer 122 may include the bias control lines GBL, the gate electrodes G5 of the fifth transistors T5, and the gate electrodes G6 of the sixth transistors T6.

The emission control line ECL that transmits an emission control signal EC to light emitting pixel drivers EPD may be disposed in the same layer as a bias voltage line VBL.

For example, the third gate conductive layer on a third gate insulating layer 125 may include the bias voltage line VBL and the emission control line ECL.

According to some embodiments of FIG. 16, the third gate conductive layer may include the bias voltage line VBL, the emission control line ECL disposed adjacent to a bias control line GBL, extending in the first direction DR1 and transmitting the emission control signal EC to the light emitting pixel drivers EPD, and an emission control auxiliary line ECAL extending in the first direction DR1 and spaced apart from the emission control line ECL in the second direction DR2.

The emission control auxiliary line ECAL may be electrically connected to the emission control line ECL through an emission control connection line ECCL extending in the second direction DR2.

The emission control connection line ECCL may cross the bias control lines GBL and the bias voltage line VBL. Accordingly, the emission control connection line ECCL may be disposed in a different gate conductive layer among the first gate conductive layer, a second gate conductive layer, and the third gate conductive layer from the bias control lines GBL and the bias voltage line VBL.

For example, the bias control lines GBL may be disposed in the first gate conductive layer, the bias voltage line VBL may be disposed in the third gate conductive layer, and the emission control connection line ECCL may be disposed in the second gate conductive layer.

For example, the second gate conductive layer on a second gate insulating layer 123 may include the emission control connection line ECCL.

However, this is only an example, and as long as the bias control lines GBL, the bias voltage line VBL, and the emission control connection line ECCL are disposed in different gate conductive layers, the arrangement structure of the lines can be changed as desired.

The emission control line ECL may overlap the first light emitting pixel driver EPD1.

The emission control auxiliary line ECAL may overlap the second light emitting pixel driver EPD2.

For example, the gate electrode G5 of the fifth transistor T5 of the first light emitting pixel driver EPD1 and the gate electrode G6 of the sixth transistor T6 of the first light emitting pixel driver EPD1 may overlap the emission control line ECL. The gate electrode G5 of the fifth transistor T5 of the first light emitting pixel driver EPD1 and the gate electrode G6 of the sixth transistor T6 of the first light emitting pixel driver EPD1 may be electrically connected to the emission control line ECL through connection holes, respectively.

In addition, the gate electrode G5 of the fifth transistor T5 of the second light emitting pixel driver EPD2 and the gate electrode G6 of the sixth transistor T6 of the second light emitting pixel driver EPD2 may overlap the emission control auxiliary line ECAL. The gate electrode G5 of the fifth transistor T5 of the second light emitting pixel driver EPD2 and the gate electrode G6 of the sixth transistor T6 of the second light emitting pixel driver EPD2 may be electrically connected to the emission control auxiliary line ECAL through connection holes, respectively, and may be electrically connected to the emission control line ECL through the emission control auxiliary line ECAL and the emission control connection line ECCL.

In this case, because the first light emitting pixel driver EPD1 and the second light emitting pixel driver EPD2 neighboring each other in the second direction DR2 share one emission control line ECL, the number of emission control lines ECL arranged in a main area MA can be reduced by about half.

Therefore, it is possible to secure wider light transmitting areas TRA in a display area DA according to the reduction in the number of emission control lines ECL without changing the number of light emitting pixel drivers EPD.

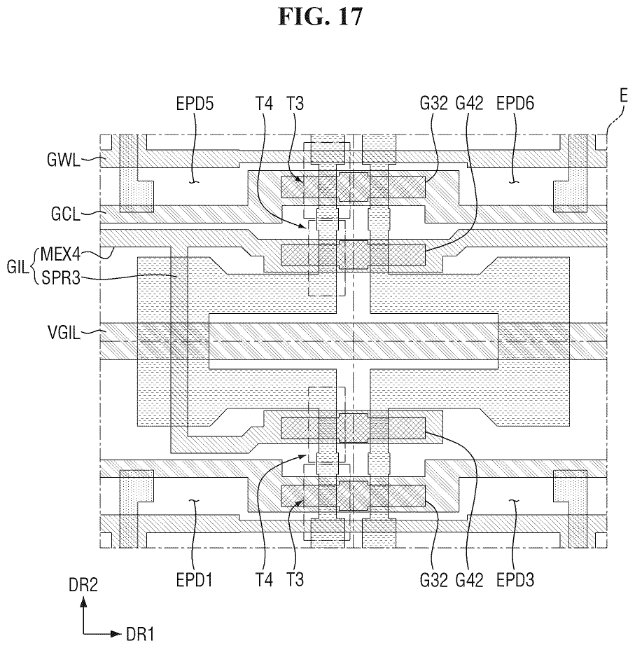

FIG. 17 is a plan view illustrating a first gate conductive layer, a second gate conductive layer, a second semiconductor layer, and a third gate conductive layer in part E of FIG. 7 according to some embodiments.

A display device 100 of some embodiments illustrated in FIG. 17 is substantially the same as those of some embodiments illustrated in FIGS. 1 through 16 except that a first light emitting pixel driver EPD1 and a fifth light emitting pixel driver EPD5 neighboring each other in the second direction DR2 share one scan initialization line GIL. Therefore, redundant descriptions will be omitted below.

Referring to FIGS. 17 and 14, the first gate conductive layer on a first gate insulating layer 122 may include the scan initialization line GIL that transmits a scan initialization signal GI to light emitting pixel drivers EPD.

The first gate conductive layer may further include a scan write line GWL that transmits a scan write signal GW to the light emitting pixel drivers EPD.

The second gate conductive layer on a second gate insulating layer 123 may include a gate initialization voltage line VGIL and a gate control line GCL.

Each of the scan initialization line GIL, the scan write line GWL, the gate initialization voltage line VGIL, and the gate control line GCL may extend in the first direction DR1.

The third gate conductive layer on a third gate insulating layer 125 may include second gate electrodes G32 of third transistors T3 and second gate electrodes G42 of fourth transistors T4.

According to some embodiments of FIG. 17, the scan initialization line GIL may include a fourth main extension portion MEX4 disposed adjacent to the gate initialization voltage line VGIL and extending in the first direction DR1 and a third sub-protruding portion SPR3 protruding from the fourth main extension portion MEX4 to extend in the second direction DR2 and crossing the gate initialization voltage line VGIL.

The fourth main extension portion MEX4 may overlap the fifth light emitting pixel driver EPD5.

An end of the third sub-protruding portion SPR3 may overlap the first light emitting pixel driver EPD1.

For example, a first gate electrode G41 of a fourth transistor T4 of the fifth light emitting pixel driver EPD5 may be provided as a portion of the fourth main extension portion MEX4, and a second gate electrode G42 of the fourth transistor T4 of the fifth light emitting pixel driver EPD5 may overlap the fourth main extension portion MEX4.

A first gate electrode G41 of a fourth transistor T4 of the first light emitting pixel driver EPD1 may be provided as a portion of the third sub-protruding portion SPR3, and a second gate electrode G42 of the fourth transistor T4 of the first light emitting pixel driver EPD1 may overlap the third sub-protruding portion SPR3.

In this case, because the first light emitting pixel driver EPD1 and the fifth light emitting pixel driver EPD5 neighboring each other in the second direction DR2 share one scan initialization line GIL, the number of scan initialization lines GIL arranged in a main area MA can be reduced by about half.

Therefore, it is possible to secure wider light transmitting areas TRA in a display area DA according to the reduction in the number of scan initialization lines GIL without changing the number of light emitting pixel drivers EPD.

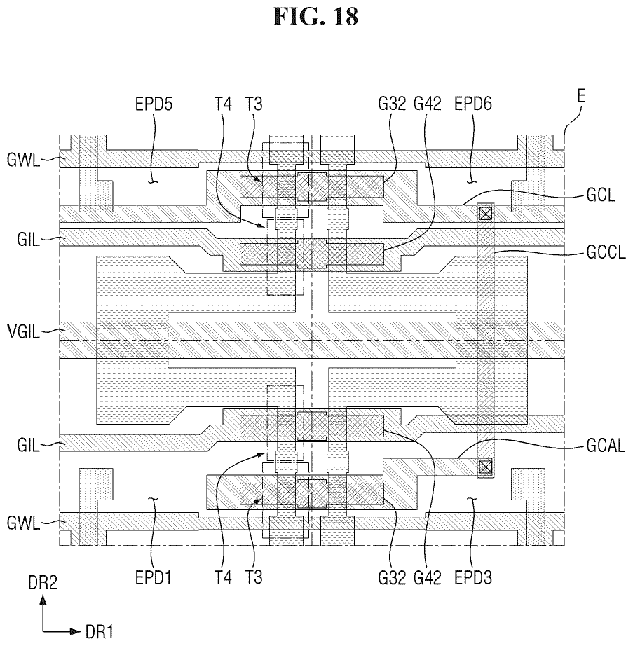

FIG. 18 is a plan view illustrating a first gate conductive layer, a second gate conductive layer, a second semiconductor layer, and a third gate conductive layer in part E of FIG. 7 according to some embodiments.

A display device 100 of some embodiments illustrated in FIG. 18 is substantially the same as those of some embodiments illustrated in FIGS. 1 through 17 except that a first light emitting pixel driver EPD1 and a fifth light emitting pixel driver EPD5 neighboring each other in the second direction DR2 share one gate control line GCL. Therefore, redundant descriptions will be omitted below.

Referring to FIGS. 18 and 14, the first gate conductive layer on a first gate insulating layer 122 may include scan initialization lines GIL that transmit scan initialization signals GI to light emitting pixel drivers EPD and scan write lines GWL that transmit scan write signals GW to the light emitting pixel drivers EPD.

According to some embodiments of FIG. 18, the second gate conductive layer on a second gate insulating layer 123 may include a gate initialization voltage line VGIL, the gate control line GCL disposed adjacent to the gate initialization voltage line VGIL, extending in the first direction DR1 and transmitting a gate control signal GC to the light emitting pixel drivers EPD, and a gate control auxiliary line GCAL extending in the first direction DR1 and spaced apart from the gate control line GCL in the second direction DR2.

The gate control auxiliary line GCAL may be electrically connected to the gate control line GCL through a gate control connection line GCCL extending in the second direction DR2.

The gate control connection line GCCL may cross the scan initialization lines GIL and the gate initialization voltage line VGIL. Accordingly, the gate control connection line GCCL may be disposed in a different gate conductive layer among the first gate conductive layer, the second gate conductive layer, and the third gate conductive layer from the scan initialization lines GIL and the gate initialization voltage line VGIL.

For example, the scan initialization lines GIL may be disposed in the first gate conductive layer, the gate initialization voltage line VGIL may be disposed in the second gate conductive layer, and the gate control connection line GCCL may be disposed in the third gate conductive layer.

For example, the third gate conductive layer on a third gate insulating layer 125 may include the gate control connection line GCCL.

However, this is only an example, and as long as the scan initialization lines GIL, the gate initialization voltage line VGIL, and the gate control connection line GCCL are disposed in different gate conductive layers, the arrangement structure of the lines can be changed as desired.

In addition, the third gate conductive layer on the third gate insulating layer 125 may include second gate electrodes G32 of third transistors T3 and second gate electrodes G42 of fourth transistors T4.

The gate control line GCL may overlap the fifth light emitting pixel driver EPD5.

The gate control auxiliary line GCAL may overlap the first light emitting pixel driver EPD1.

For example, a first gate electrode G31 of a third transistor T3 of the fifth light emitting pixel driver EPD5 may be provided as a portion of the gate control line GCL, and a second gate electrode G32 of the third transistor T3 of the fifth light emitting pixel driver EPD5 may overlap the gate control line GCL.

A first gate electrode G31 of a third transistor T3 of the first light emitting pixel driver EPD1 may be provided as a portion of the gate control auxiliary line GCAL, and a second gate electrode G32 of the third transistor T3 of the first light emitting pixel driver EPD1 may overlap the gate control auxiliary line GCAL.

In this case, because the first light emitting pixel driver EPD1 and the fifth light emitting pixel driver EPD5 neighboring each other in the second direction DR2 share one gate control line GCL, the number of gate control lines GCL arranged in a main area MA can be reduced by about half.

Therefore, it is possible to secure wider light transmitting areas TRA in a display area DA according to the reduction in the number of gate control lines GCL without changing the number of light emitting pixel drivers EPD.

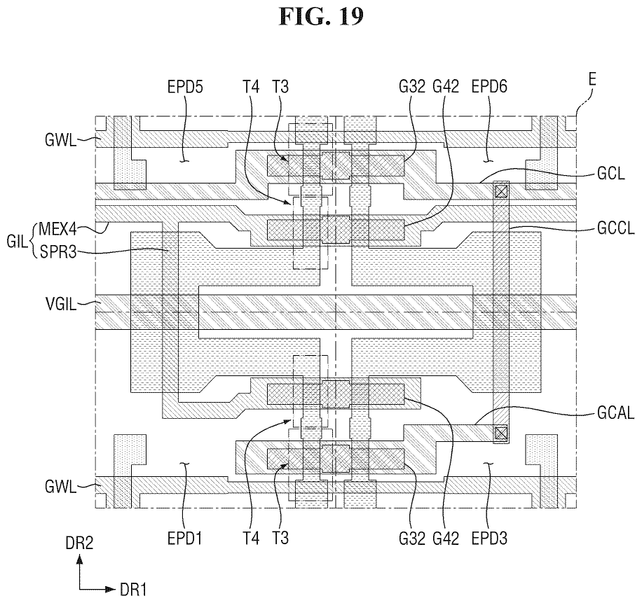

FIG. 19 is a plan view illustrating a first gate conductive layer, a second gate conductive layer, a second semiconductor layer, and a third gate conductive layer in part E of FIG. 7 according to some embodiments.

According to some embodiments illustrated in FIG. 19, a first light emitting pixel driver EPD1 and a fifth light emitting pixel driver EPD5 neighboring each other in the second direction DR2 may share one scan initialization line GIL and one gate control line GCL.

For example, some embodiments of FIG. 19 are a combination of some embodiments of FIG. 17 and some embodiments of FIG. 18. Therefore, redundant descriptions will be omitted below.

In this case, it is possible to secure wider light transmitting areas TRA in a display area DA according to a reduction in the number of scan initialization lines GIL and the number of gate control lines GCL without changing the number of light emitting pixel drivers EPD.

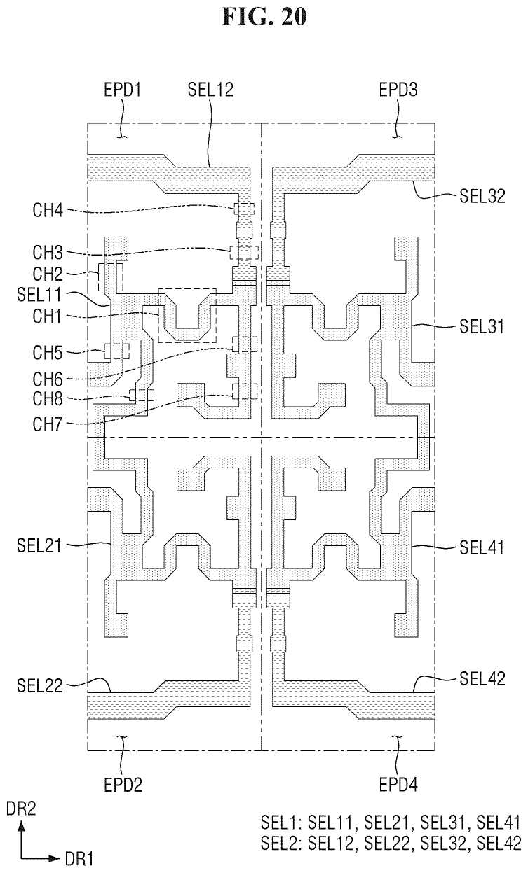

FIG. 20 is a plan view illustrating a first semiconductor layer and a second semiconductor layer of each of a first light emitting pixel driver EPD1, a second light emitting pixel driver EPD2, a third light emitting pixel driver EPD3, and a fourth light emitting pixel driver EPD4 according to some embodiments.

As illustrated in FIG. 20, according to some embodiments, a first semiconductor layer SEL1 on a substrate 110 may include a channel portion CH1, CH2, CH5, CH6, CH7, and/or CH8 of each of a first transistor T1, a second transistor T2, a fifth transistor T5, a sixth transistor T6, a seventh transistor T7 and an eighth transistor T8 and a first electrode portion and a second electrode portion connected to both ends of the channel portion CH1, CH2, CH5, CH6, CH7, and/or CH8.

A second semiconductor layer SEL2 may include a channel portion CH3 or CH4 of each of a third transistor T3 and a fourth transistor T4 and a first electrode portion and a second electrode portion connected to both ends of the channel portion CH3 or CH4.

Referring to FIG. 20, in a circuit layer 120 of a display device 100 according to some embodiments, a first semiconductor layer SEL11 and a second semiconductor layer SEL12 of the first light emitting pixel driver EPD1 may be symmetrical to a first semiconductor layer SEL31 and a second semiconductor layer SEL32 of the third light emitting pixel driver EPD3 with respect to a boundary between the first light emitting pixel driver EPD1 and the third light emitting pixel driver EPD3.

In addition, according to some embodiments, the first semiconductor layer SEL11 and the second semiconductor layer SEL12 of the first light emitting pixel driver EPD1 may be symmetrical to a first semiconductor layer SEL21 and a second semiconductor layer SEL22 of the second light emitting pixel driver EPD2 with respect to a boundary between the first light emitting pixel driver EPD1 and the second light emitting pixel driver EPD2.

In this case, a structure in which at least one of a bias voltage line VBL, an anode initialization voltage line VAIL, a bias control line GBL, an emission control line ECL, a gate initialization voltage line VGIL, a scan initialization line GIL, and a gate control line GCL, which are adjacent to a boundary between light emitting pixel drivers EPD neighboring each other in the second direction DR2 and extend in the first direction DR1, is shared by the light emitting pixel drivers EPD neighboring each other in the second direction DR2 can be easily implemented.

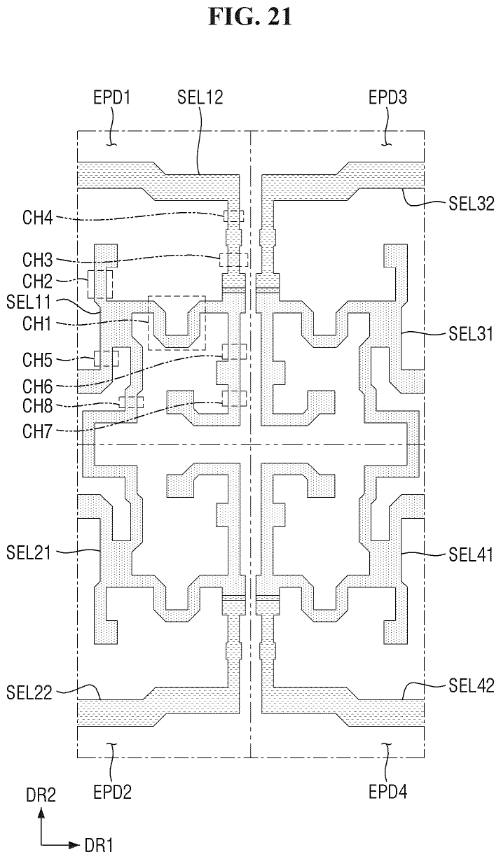

FIG. 21 is a plan view illustrating a first semiconductor layer and a second semiconductor layer of each of a first light emitting pixel driver EPD1, a second light emitting pixel driver EPD2, a third light emitting pixel driver EPD3, and a fourth light emitting pixel driver EPD4, according to some embodiments.

A display device 100 according to some embodiments illustrated in FIG. 21 is substantially the same as that of some embodiments of FIG. 20 except that channel portions CH1 of first transistors T1 of light emitting pixel drivers EPD are congruent. Therefore, redundant descriptions will be omitted below.

According to some embodiments of FIG. 21, a first semiconductor layer SEL11 and a second semiconductor layer SEL12 of the first light emitting pixel driver EPD1 excluding a channel portion CH1 of a first transistor T1 may be symmetrical to a first semiconductor layer SEL21 and a second semiconductor layer SEL22 of the second light emitting pixel driver EPD2 excluding a channel portion CH1 of a first transistor T1 with respect to a boundary between the first light emitting pixel driver EPD1 and the second light emitting pixel driver EPD2.

In addition, the channel portion CH1 of the first transistor T1 of the first light emitting pixel driver EPD1 may be congruent with the channel portion CH1 of the first transistor T1 of the second light emitting pixel driver EPD2.

For example, in all light emitting pixel drivers EPD, the channel portions CH1 of the first transistors T1 may be disposed in a ‘U’ shape that is convex toward one side in the second direction DR2 (a lower side in FIG. 21). However, the illustration in FIG. 21 is only an example, and the channel portions CH1 of the first transistors T1 may also be modified into other shapes.

In this case, in a process of crystallizing first semiconductor layer SEL11, SEL21, SEL31, and SEL41 using laser beams, the channel portions CH1 of the first transistors T1 of the light emitting pixel drivers EPD may be similarly irradiated with the laser beams. Therefore, the uniformity of semiconductor characteristics of the channel portions CH1 of the first transistors T1 can be improved. Accordingly, this can reduce stain defects, thereby improving the display quality of the display device 100.

A display device according to some embodiments may include a substrate, a circuit layer, and an element layer. The substrate may include a display area in which emission areas are arranged. The element layer may include light emitting elements disposed in the emission areas, respectively.

The circuit layer may include light emitting pixel drivers which are electrically connected to the light emitting elements of the element layer, respectively, and arranged side by side with each other, a data line which transmits a data signal to the light emitting pixel drivers, and a bias voltage line which extends in a first direction crossing the data line.

The light emitting pixel drivers include a first light emitting pixel driver and a second light emitting pixel driver neighboring each other in a second direction crossing the first direction.

The first light emitting pixel driver and the second light emitting pixel driver may be electrically connected to one bias voltage line disposed adjacent to a boundary between the first light emitting pixel driver and the second light emitting pixel driver.

For example, according to some embodiments, the first light emitting pixel driver and the second light emitting pixel driver may not be electrically connected to two bias voltage lines, but may share one bias voltage line. Accordingly, because one bias voltage line is removed, an area between the first light emitting pixel driver and the second light emitting pixel driver can be provided as a light transmitting area in which conductive layers are not disposed.

Therefore, even if the number of light emitting pixel drivers is not reduced, a light transmitting area for providing an optical path of optical sensors can be secured. Accordingly, even if a portion of the display area overlaps the optical sensors, deterioration of display quality can be reduced or prevented.

In addition, according to some embodiments, the light emitting pixel drivers may further include a third light emitting pixel driver and a fourth light emitting pixel driver respectively neighboring the first light emitting pixel driver and the second light emitting pixel driver in the first direction.

One bias voltage line disposed adjacent to the boundary between the first light emitting pixel driver and the second light emitting pixel driver may include a first main extension portion extending in the first direction and a bypass portion connected to the first main extension portion and bypassing a light transmitting area including a contact point at which the first light emitting pixel driver, the second light emitting pixel driver, the third light emitting pixel driver, and the fourth light emitting pixel driver contact each other.

For example, according to some embodiments, because one bias voltage line does not extend in a straight line in the first direction but includes the bypass portion that bypasses the light transmitting area, a wider light transmission area can be secured.

However, the effects of the present disclosure are not restricted to the ones set forth herein. The above and other effects of the present disclosure will become more apparent to one of ordinary skill in the art to which the present disclosure pertains by referencing the claims.

The foregoing is illustrative of some embodiments of the present disclosure, and is not to be construed as limiting thereof. Although some embodiments have been described, those skilled in the art will readily appreciate that various modifications are possible in some embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a substrate comprising a display area including emission areas;
a circuit layer on the substrate; and
an element layer on the circuit layer, and comprising light emitting elements in the emission areas, respectively,
wherein the circuit layer comprises:
light emitting pixel drivers electrically connected to the light emitting elements, respectively, and located side by side with each other in a first direction and a second direction crossing the first direction, the light emitting pixel drivers comprising:
a first light emitting pixel driver and a second light emitting pixel driver adjacent to each other in the second direction; and
a third light emitting pixel driver and a fourth light emitting pixel driver adjacent to the first light emitting pixel driver and the second light emitting pixel driver, respectively, in the first direction; and
one first-direction line extending in the first direction, and adjacent to a boundary between the first light emitting pixel driver and the second light emitting pixel driver, and to a boundary between the third light emitting pixel driver and the fourth light emitting pixel driver,
wherein the one first-direction line comprises:
a first main extension portion extending in the first direction; and
a bypass portion connected to the first main extension portion, and bypassing a light transmitting area of the display area comprising a contact point at which the first light emitting pixel driver, the second light emitting pixel driver, the third light emitting pixel driver, and the fourth light emitting pixel driver contact each other.

2. The display device of claim 1, wherein:
the first light emitting pixel driver, the second light emitting pixel driver, the third light emitting pixel driver, and the fourth light emitting pixel driver are electrically connected to the one first-direction line; and
the one first-direction line is one of a plurality of bias voltage lines configured to transmit bias voltages to the light emitting pixel drivers.

3. The display device of claim 2, wherein the circuit layer further comprises an anode initialization voltage line configured to transmit an anode initialization voltage to the light emitting pixel drivers,
wherein the anode initialization voltage line comprises:
a second main extension portion adjacent to the first main extension portion, and extending in the first direction; and
a first sub-protruding portion protruding from the second main extension portion to extend in the second direction, and crossing the one first-direction line, and
wherein:
the second main extension portion overlaps with the first light emitting pixel driver; and
an end of the first sub-protruding portion overlaps with the second light emitting pixel driver.

4. The display device of claim 2, wherein the circuit layer further comprises:
a first anode initialization voltage line adjacent to a side of the one of the plurality of bias voltage lines in the second direction, extending in the first direction, and configured to transmit a first anode initialization voltage; and
a second anode initialization voltage line adjacent to another side of the one of the plurality of bias voltage lines in the second direction, extending in the first direction, and configured to transmit a second anode initialization voltage having a different voltage level from that of the first anode initialization voltage, and
wherein:
the first anode initialization voltage line overlaps with the first light emitting pixel driver, and is electrically connected to the first light emitting pixel driver and the second light emitting pixel driver; and
the second anode initialization voltage line overlaps with the fourth light emitting pixel driver, and is electrically connected to the third light emitting pixel driver and the fourth light emitting pixel driver.

5. The display device of claim 2, wherein the circuit layer further comprises a bias control line configured to transmit a bias control signal to the light emitting pixel drivers,
wherein the bias control line comprises:
a third main extension portion adjacent to a side of the one of the plurality of bias voltage lines in the second direction, and extending in the first direction; and
a second sub-protruding portion protruding from the third main extension portion to extend in the second direction, and crossing the one first-direction line, and
wherein:
the third main extension portion overlaps with the first light emitting pixel driver; and
an end of the second sub-protruding portion overlaps with the second light emitting pixel driver.

6. The display device of claim 5, wherein the circuit layer further comprises:
an emission control line adjacent to the bias control line, extending in the first direction, and overlapping with the first light emitting pixel driver and the third light emitting pixel driver, the emission control line being configured to transmit an emission control signal to the light emitting pixel drivers;
an emission control auxiliary line extending in the first direction, spaced from the emission control line in the second direction, and overlapping with the second light emitting pixel driver and the fourth light emitting pixel driver; and
an emission control connection line extending in the second direction, electrically connected to the emission control line and the emission control auxiliary line, and crossing the one first-direction line.

7. The display device of claim 2, wherein:
the circuit layer further comprises a gate initialization voltage line configured to transmit a gate initialization voltage to the light emitting pixel drivers;
the light emitting pixel drivers further comprise a fifth light emitting pixel driver adjacent to the first light emitting pixel driver in the second direction;
the first light emitting pixel driver is located between the second light emitting pixel driver and the fifth light emitting pixel driver in the second direction; and
the first light emitting pixel driver and the fifth light emitting pixel driver are electrically connected to one gate initialization voltage line located adjacent to a boundary between the first light emitting pixel driver and the fifth light emitting pixel driver.

8. The display device of claim 7, wherein the circuit layer further comprises a scan initialization line configured to transmit a scan initialization signal to the light emitting pixel drivers,
wherein the scan initialization line comprises:
a fourth main extension portion adjacent to the gate initialization voltage line, and extending in the first direction; and
a third sub-protruding portion protruding from the fourth main extension portion, and extending in the second direction, and
wherein:
the fourth main extension portion overlaps with the fifth light emitting pixel driver, and
an end of the third sub-protruding portion overlaps with the first light emitting pixel driver.

9. The display device of claim 7, wherein the circuit layer further comprises:
a gate control line extending in the first direction, overlapping with the fifth light emitting pixel driver, and configured to transmit a gate control signal to the light emitting pixel drivers;
a gate control auxiliary line spaced from the gate control line in the second direction, extending in the first direction, and overlapping with the first light emitting pixel driver; and
a gate control connection line extending in the second direction, electrically connected to the gate control line and the gate control auxiliary line, and crossing the gate initialization voltage line.

10. The display device of claim 2,
wherein the circuit layer further comprises:
a first semiconductor layer on the substrate;
a first gate insulating layer covering the first semiconductor layer;
a first gate conductive layer on the first gate insulating layer;
a second gate insulating layer covering the first gate conductive layer;
a second gate conductive layer on the second gate insulating layer;
a first interlayer insulating layer covering the second gate conductive layer;
a second semiconductor layer on the first interlayer insulating layer;
a third gate insulating layer covering the second semiconductor layer;
a third gate conductive layer on the third gate insulating layer;
a second interlayer insulating layer covering the third gate conductive layer;
a first source-drain conductive layer on the second interlayer insulating layer;
a first planarization layer covering the first source-drain conductive layer;
a second source-drain conductive layer on the first planarization layer; and
a second planarization layer covering the second source-drain conductive layer,
wherein each of the light emitting pixel drivers comprises:
a first transistor electrically connected between a first node and a second node;
a pixel capacitor electrically connected between a first power line and a third node, the first power line being configured to transmit a first power;
a second transistor electrically connected between a data line and the first node, the data line being configured to transmit a data signal;
a third transistor electrically connected between the second node and the third node;
a fourth transistor electrically connected between a gate initialization voltage line and the third node, the gate initialization voltage line being configured to transmit a gate initialization voltage;
a fifth transistor electrically connected between the first power line and the first node;
a sixth transistor electrically connected between the second node and a fourth node;
a seventh transistor electrically connected between an anode initialization voltage line and the fourth node, the anode initialization voltage line being configured to transmit an anode initialization voltage; and
an eighth transistor electrically connected between the one of the plurality of bias voltage lines and the first node,
wherein:
the first node is electrically connected to a first electrode of the first transistor;
the second node is electrically connected to a second electrode of the first transistor;
the third node is electrically connected to a gate electrode of the first transistor; and
the fourth node is electrically connected to one of the light emitting elements,
wherein each of the first transistor, the second transistor, the fifth transistor, the sixth transistor, the seventh transistor, and the eight transistor comprises:
a gate electrode;
a channel portion overlapping with the gate electrode;
a first electrode portion connected to a side of the channel portion; and
a second electrode portion connected to another side of the channel portion,
wherein each of the third transistor and the fourth transistor comprises:
a first gate electrode and a second gate electrode at least partially overlapping with each other;
a channel portion between the first gate electrode and the second gate electrode;
a first electrode portion connected to a side of the channel portion; and
a second electrode portion connected to another side of the channel portion, and
wherein:
the channel portion, the first electrode portion, and the second electrode portion of each of the first transistor, the second transistor, the fifth transistor, the sixth transistor, the seventh transistor, and the eighth transistor are parts of the first semiconductor layer; and
the channel portion, the first electrode portion, and the second electrode portion of each of the third transistor and the fourth transistor are parts of the second semiconductor layer.

11. The display device of claim 10, wherein the first semiconductor layer and the second semiconductor layer of the first light emitting pixel driver are symmetrical to the first semiconductor layer and the second semiconductor layer of the third light emitting pixel driver with respect to a boundary between the first light emitting pixel driver and the third light emitting pixel driver.

12. The display device of claim 11, wherein the first semiconductor layer of the first light emitting pixel driver is symmetrical to the first semiconductor layer of the second light emitting pixel driver with respect to the boundary between the first light emitting pixel driver and the second light emitting pixel driver.

13. The display device of claim 11, wherein the channel portion of the first transistor of the first light emitting pixel driver is congruent with the channel portion of the first transistor of the second light emitting pixel driver.

14. A display device comprising:
a substrate comprising a display area including emission areas;
a circuit layer on the substrate; and
an element layer on the circuit layer, and comprising light emitting elements in the emission areas, respectively,
wherein the circuit layer comprises:
light emitting pixel drivers electrically connected to the light emitting elements, respectively, and located side by side with each other in a first direction and a second direction crossing the first direction;
a first semiconductor layer on the substrate;
a first gate insulating layer covering the first semiconductor layer;
a first gate conductive layer on the first gate insulating layer;
a second gate insulating layer covering the first gate conductive layer;
a second gate conductive layer on the second gate insulating layer;
a first interlayer insulating layer covering the second gate conductive layer;
a second semiconductor layer on the first interlayer insulating layer;
a third gate insulating layer covering the second semiconductor layer;
a third gate conductive layer on the third gate insulating layer; and
a second interlayer insulating layer covering the third gate conductive layer,
wherein each of the light emitting pixel drivers comprises:
a first transistor electrically connected between a first node and a second node;
a pixel capacitor electrically connected between a first power line and a third node, the first power line being configured to transmit a first power;
a second transistor electrically connected between a data line and the first node, the data line being configured to transmit a data signal;
a third transistor electrically connected between the second node and the third node; and
a fourth transistor electrically connected between a gate initialization voltage line and the third node, the gate initialization voltage line being configured to transmit a gate initialization voltage,
wherein:
the first node is electrically connected to a first electrode of the first transistor;
the second node is electrically connected to a second electrode of the first transistor; and
the third node is electrically connected to a gate electrode of the first transistor,
wherein each of the first transistor and the second transistor comprises:
a gate electrode;
a channel portion overlapping with the gate electrode;
a first electrode portion connected to a side of the channel portion; and
a second electrode portion connected to another side of the channel portion,
wherein each of the third transistor and the fourth transistor comprises:
a first gate electrode and a second gate electrode at least partially overlapping with each other;
a channel portion between the first gate electrode and the second gate electrode;
a first electrode portion connected to a side of the channel portion; and
a second electrode portion connected to another side of the channel portion,
wherein:
the channel portion, the first electrode portion, and the second electrode portion of each of the first transistor and the second transistor are parts of the first semiconductor layer; and
the channel portion, the first electrode portion, and the second electrode portion of each of the third transistor and the fourth transistor are parts of the second semiconductor layer,
wherein the light emitting pixel drivers comprise a first light emitting pixel driver and a second light emitting pixel driver adjacent to each other in the second direction, and
wherein the channel portion of the first transistor of the first light emitting pixel driver is congruent with the channel portion of the first transistor of the second light emitting pixel driver.

15. The display device of claim 14, wherein:
the light emitting pixel drivers further comprise a third light emitting pixel driver and a fourth light emitting pixel driver adjacent to the first light emitting pixel driver and the second light emitting pixel driver, respectively, in the first direction;
the circuit layer further comprises one first-direction line extending in the first direction, and adjacent to a boundary between the first light emitting pixel driver and the second light emitting pixel driver, and to a boundary between the third light emitting pixel driver and the fourth light emitting pixel driver;
the first light emitting pixel driver, the second light emitting pixel driver, the third light emitting pixel driver, and the fourth light emitting pixel driver are electrically connected to the one first-direction line; and
the one first-direction line comprises:
a first main extension portion extending in the first direction; and
a bypass portion connected to the first main extension portion and bypassing a light transmitting area of the display area comprising a contact point at which the first light emitting pixel driver, the second light emitting pixel driver, the third light emitting pixel driver, and the fourth light emitting pixel driver contact each other.

16. The display device of claim 15, wherein each of the light emitting pixel drivers further comprises:
a fifth transistor electrically connected between the first power line and the first node;
a sixth transistor electrically connected between the second node and a fourth node;
a seventh transistor electrically connected between an anode initialization voltage line and the fourth node, the anode initialization voltage line being configured to transmit an anode initialization voltage; and
an eighth transistor electrically connected between a bias voltage line and the first node, the bias voltage line being configured to transmit a bias voltage,
wherein the fourth node is electrically connected to one of the light emitting elements, and
wherein the one first-direction line is the bias voltage line.

17. The display device of claim 16, wherein the anode initialization voltage line comprises:
a second main extension portion adjacent to the first main extension portion of the bias voltage line, and extending in the first direction; and
a first sub-protruding portion protruding from the second main extension portion to extend in the second direction, and crossing the one first-direction line, and
wherein:
the second main extension portion overlaps with the first light emitting pixel driver; and
an end of the first sub-protruding portion overlaps with the second light emitting pixel driver.

18. The display device of claim 16, wherein the circuit layer further comprises:
a first anode initialization voltage line adjacent to a side of the bias voltage line in the second direction, extending in the first direction, and configured to transmit a first anode initialization voltage; and
a second anode initialization voltage line adjacent to another side of the bias voltage line in the second direction, extending in the first direction, and configured to transmit a second anode initialization voltage having a different voltage level from that of the first anode initialization voltage, and
wherein:
the first anode initialization voltage line overlaps with the first light emitting pixel driver, and is electrically connected to the first light emitting pixel driver and the second light emitting pixel driver; and
the second anode initialization voltage line overlaps with the fourth light emitting pixel driver, and is electrically connected to the third light emitting pixel driver and the fourth light emitting pixel driver.

19. The display device of claim 16, wherein:
the circuit layer further comprises a bias control line configured to transmit a bias control signal to the light emitting pixel drivers;
the seventh transistor and the eighth transistor are configured to be turned on by the bias control signal;
the bias control line comprises:
a third main extension portion adjacent to a side of the bias voltage line in the second direction, and extending in the first direction; and
a second sub-protruding portion protruding from the third main extension portion to extend in the second direction, and crossing the one first-direction line;
the third main extension portion overlaps with the first light emitting pixel driver; and
an end of the second sub-protruding portion overlaps with the second light emitting pixel driver.

20. The display device of claim 16, wherein the light emitting pixel drivers further comprise a fifth light emitting pixel driver adjacent to the first light emitting pixel driver in the second direction,
wherein the first light emitting pixel driver is located between the second light emitting pixel driver and the fifth light emitting pixel driver in the second direction, and
wherein the first light emitting pixel driver and the fifth light emitting pixel driver are electrically connected to one gate initialization voltage line adjacent to a boundary between the first light emitting pixel driver and the fifth light emitting pixel driver.
